(19) United States
(12) Patent Application Publication
(10) Pub. No.: US 2025/0311601 A1
(43) Pub. Date: Oct. 2, 2025

(54) LIGHT-EMITTING APPARATUS, DISPLAY APPARATUS, PHOTOELECTRIC-CONVERSION APPARATUS, AND ELECTRONIC EQUIPMENT

(71) Applicant: CANON KABUSHIKI KAISHA, Tokyo (JP)

(72) Inventor: SHOMA HINATA, Kanagawa (JP)

(21) Appl. No.: 19/094,491

(22) Filed: Mar. 28, 2025

(30) Foreign Application Priority Data
Apr. 2, 2024 (JP) 2024-059798
Jan. 27, 2025 (JP) 2025-011103

(51) Int. Cl. H10K 59/80

(52) U.S. Cl. CPC H10K 59/879; H10K 59/878

(57) ABSTRACT

A light-emitting apparatus includes a substrate; a light-emission portion including a reflective layer, an organic layer, and a conductive layer; and a lens overlapping at least part of the light-emission portion in a plan view for the substrate. The lens has a positive power and a convex shape. The vertex of the lens does not coincide with the center of the light-emission portion in a plan view. The reflective layer has an incline portion, and a normal line of the reflective layer at a point of which the distance from the vertex is the largest in a direction parallel to the main surface of the substrate and a line passing through the vertex and perpendicular to a line passing through both ends of the lens intersect at one point which coincides with the vertex or is located on the light-extraction side than the vertex.

### BACKGROUND

### Field of the Disclosure

The present disclosure relates to a light-emitting apparatus, a display apparatus, a photoelectric-conversion apparatus, and electronic equipment.

### Description of the Related Art

In order to improve the performance of a light-emitting apparatus, it may be required to increase the efficiency of not only light extraction in a front direction but also light extraction in a diagonal direction. In particular, when a light emission display is used as a display apparatus such as a head mount display, it may be used in combination with an optical system such as a pancake lens. In such a case, in the peripheral portion of the display region, light emitted in an oblique direction is mainly used, and in order to improve the display quality in the peripheral portion of the display region, it may be required to increase the light-extraction efficiency in the diagonal direction.

When a light-emitting apparatus is used as an exposure apparatus of a photoreceptor, it may be used in combination with an optical system such as a SELFOC® lens. When light-emission portions and the centers of optical systems are arranged so as to be displaced from each other such as when a plurality of light-emission portions are arranged zigzag, in order to improve the light use efficiency, it may be required to improve the light-extraction efficiency in a diagonal direction from the light-emission portion toward the center of the optical system.

In order to improve the efficiency of light extraction in a diagonal direction in an organic light-emitting apparatus, Japanese Patent Laid-Open No. 2019-133816 describes a light-emitting device having an on-chip microlens that disperses light from an organic layer in which the on-chip microlens and a light-emission portion are formed in a misaligned manner.

### SUMMARY

The performance of a light-emitting apparatus can be further improved by further efficiently extracting light emitted from the light-emission portion in a diagonal direction.

One aspect of the present disclosure provides technique advantageous for improving the efficiency of light extraction in a diagonal direction.

One aspect of the present disclosure relates to a light-emitting apparatus comprising a substrate; a first light-emission portion including a reflective layer disposed on a main surface of the substrate, an organic layer disposed on the reflective layer, and a conductive layer disposed on the organic layer; and a first lens disposed so as to at least partially overlap the first light-emission portion in a plan view from a direction perpendicular to the main surface of the substrate, wherein the first lens has a positive power and has a convex shape in an opposite direction to the substrate; and wherein, in a cross section passing through a vertex of the convex shape of the first lens and perpendicular to the main surface, when a middle point of a line segment connecting one end and another end of the first light-emission portion is defined as a center of the first light-emission portion, in the plan view, the vertex of the first lens is spaced apart from the center of the first light-emission portion by a first distance, and, in the cross section, the reflective layer includes an incline portion inclined with respect to the main surface, and in the incline portion of the reflective layer, when a point of which the distance from the vertex of the first lens in a direction parallel to the main surface is the largest is defined as a first position, a first straight line passes through both ends of the first lens, a second straight line extends in a direction perpendicular to the first straight line and passes through the vertex of the first lens, the second straight line and a normal line of the reflective layer at the first position of the incline portion intersect with each other at one point, and the one point corresponds to the vertex of the first lens or is located on the light-extraction side than the vertex of the first lens.

Further features of various embodiments will become apparent from the following description of exemplary embodiments with reference to the attached drawings.

### BRIEF DESCRIPTION OF THE DRAWINGS

FIGS. 1A and 1B are diagrams illustrating configuration examples of the light-emitting apparatus of an embodiment.

FIG. 2 is a diagram illustrating a configuration example of a light-emitting apparatus of a comparative example.

FIG. 3 is a graph for explaining an example embodiment and the comparative example.

FIG. 4 is a diagram illustrating a configuration example of a light-emitting apparatus of a comparative example.

FIGS. 5A to 5C are diagrams illustrating configuration examples of the light-emitting apparatus of the present embodiments.

FIG. 6 is a diagram illustrating a configuration example of a light-emitting apparatus of the present embodiments.

FIG. 7 is a diagram illustrating a configuration example of a light-emitting apparatus of the present embodiments.

FIGS. 8A to 8E are diagrams illustrating configuration examples of the reflective layer of the light-emitting apparatus of the present embodiments.

FIGS. 9A to 9C are diagrams illustrating arrangement examples of the light-emitting devices of the light-emitting apparatus of the present embodiments.

FIG. 10 is a diagram illustrating an example of a display apparatus using the light-emitting apparatus of the present embodiments.

FIG. 11 is a diagram illustrating an example of a photoelectric-conversion apparatus using the light-emitting apparatus of the present embodiments.

FIG. 12 is a diagram illustrating an example of electronic equipment using the light-emitting apparatus of the present embodiments.

FIGS. 13A and 13B are diagrams illustrating examples of a display apparatus using the light-emitting apparatus of the present embodiments.

FIG. 14 is a diagram illustrating an example of an illumination apparatus using the light-emitting apparatus of the present embodiments.

FIG. 15 is a diagram illustrating an example of a moving body using the light-emitting apparatus of the present embodiments.

FIGS. 16A and 16B are diagrams illustrating examples of a wearable device using the light-emitting apparatus of the present embodiments.

FIGS. 17A to 17C show an image-forming apparatus according to the present embodiments.

FIG. 18A is a schematic view illustrating the planar shapes in the configuration example of FIG. 8D, and FIGS. 18B to 18D are schematic views of extracted planar shapes of the reflective layer, light-emission portion, and incline portion in other configuration examples of the light-emitting apparatus of the present embodiments.

### DESCRIPTION OF THE EMBODIMENTS

Embodiments will now be described in detail with reference to the attached drawings. The following embodiments do not limit the scope of every embodiment according to claims. Although the embodiments include a plurality of features, not all of these features are essential to every embodiment, and the features may be combined in any manner. Furthermore, in the attached drawings, the same reference numbers are used for the same or similar components, and duplicate explanations will be omitted.

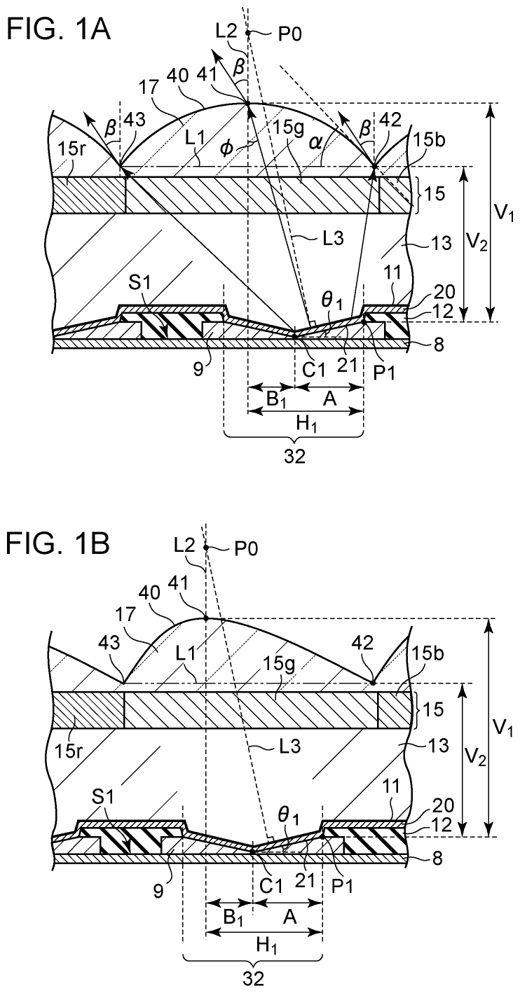

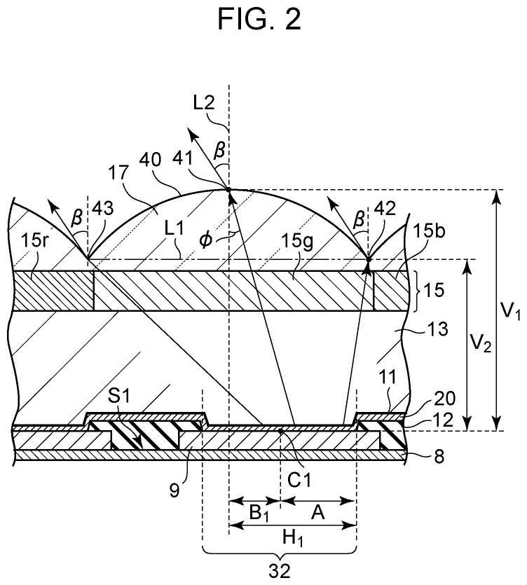

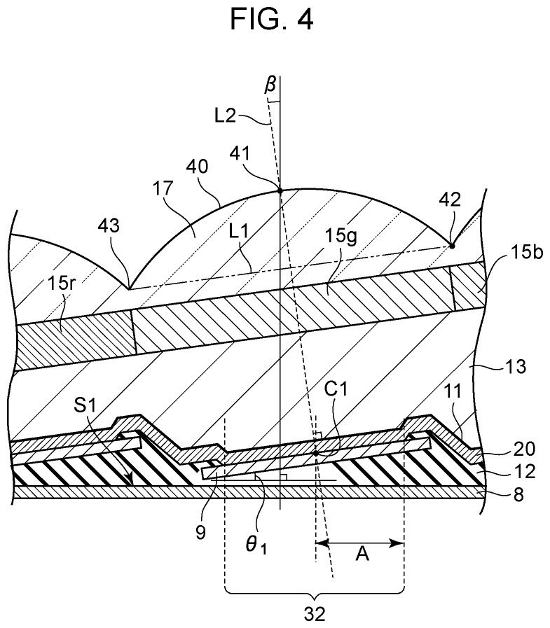

A light-emitting apparatus according to an embodiment of the present disclosure will be described with reference to FIGS. 1A and 1B to 9A to 9C. FIGS. 1A and 1B are cross-sectional views respectively illustrating configuration examples of the light-emitting apparatus of the present embodiments. FIGS. 2 and 4 are cross-sectional views illustrating configuration examples of a light-emitting apparatus of comparative examples.

The light-emitting apparatus includes a substrate 8, a lens 17 arranged on a main surface of the substrate 8, and a light-emission portion 32 that can be disposed between the main surface of the substrate 8 and the lens 17. A protection layer 13 and a color-filter layer 15 (color filter 15) are arranged between the light-emission portion 32 and the lens 17. Either of these two layers or both of them together may be considered as a medium layer. The light-emission portion 32 includes a reflective layer 9, an organic layer 20, and a conductive layer 11 in this order from the substrate 8 side.

The reflective layer 9 and the conductive layer 11 may be a first electrode and a second electrode, respectively, of a light-emitting device. In the configuration examples of FIGS. 1A and 1B, the reflective layer 9 includes an incline portion 21 inclined with respect to the main surface of the substrate 8. In the examples of FIGS. 1A and 1B, the end of the incline portion 21 and the end of the light-emission portion 32 correspond to each other. It can be comprehended that the incline portion 21 has a positive inclination angle θ in a direction toward the vertex of the first lens.

The reflective layer 9 has a symmetrical shape with the center C1 of the light-emission portion 32 as the axis and can also be comprehended to have a conical shape. In examples of FIGS. 1A and 1B, in the cross-sectional views, the reflective layer 9 is linear from the center C1 to the end P1 of the incline portion 21. That is, the reflective layer 9 has a constant inclination angle θ₁ from the center C1 to the end P1 of the incline portion 21.

In the comparative example of FIG. 2, the reflective layer 9 is formed in a flat plate shape parallel to the main surface of the substrate. That is, the comparative example of FIG. 2 does not include an incline portion. In the examples of FIGS. 1A and 1B and the comparative example of FIG. 2, the organic layer 20 and the conductive layer 11 are formed along the shape of the reflective layer 9. That is, in the examples of FIGS. 1A and 1B, it can be comprehended that the organic layer 20 and the conductive layer 11 also have an incline portion with an inclination angle θ. Similarly, it can also be comprehended that the light-emission portion 32 includes an incline portion with an inclination angle θ.

The surface of the protection layer 13 on the substrate 8 side is formed along the incline portion, and the surface on the lens 17 side is formed parallel to the main surface of the substrate. In FIGS. 1A, 1B, and 2, in order to explain the shapes of the reflective layer 9 and lens 17 in detail, configurations other than those described above are omitted, but the detailed configuration of the light-emitting apparatus is described later.

The light-emission portion 32 and the lens 17 are disposed so as to partially overlap each other in a plan view from a direction perpendicular to the main surface S1 of the substrate 8. As shown in FIGS. 1A and 1B, in the same plan view, the center of the light-emission portion 32 is disposed not to overlap the vertex 41 of the lens 17 and to have a distance B1 from the center. The distance B1 is appropriately determined depending on the light-extraction angle that is required for the light-emitting apparatus. Here, the term “a position (member) A and a position (member) B are arranged so as to have a distance X” does not include the case where the distance X is zero.

The center of the light-emission portion 32 can be defined as a position of the geometric centroid of the light-emission portion 32 in an orthographic projection to the main surface S1 of the substrate 8. For example, the center of the light-emission portion 32 can be defined as the middle point of a line segment connecting one end to the other end of the light-emission portion in a cross section passing through the vertex 41 of the lens 17 and perpendicular to the main surface of the substrate 8.

The lens 17 can also be called a microlens or the like. The upper surface of the lens 17 has a convex-shaped curved surface 40 in a direction away from the main surface S1 of the substrate 8. Light emitted from the light-emission portion 32 obliquely outward (a direction away from the center of the light-emission portion in a plan view from a direction perpendicular to the main surface S1 of the substrate 8) is converted into parallel light (collimate light) by refraction at the curved surface 40 of the lens 17 and can be extracted in the front direction. That is, the lens 17 can function as a collimator. The lens 17 may have a light-harvesting property. The lens 17 can have a positive power that converts light emitted from the light-emission portion 32 into parallel light or convergent light.

In the present embodiments, the curved surface 40 may be a part of a spherical surface or may be a part of an aspherical surface, such as a paraboloid and a hyperboloid. Examples in which the curved surface 40 is a part of spherical surface are shown in FIGS. 1A and 2, and an example in which the curved surface 40 is an aspherical surface is shown in FIG. 1B.

The convex-shaped curved surface 40 includes an end (second position, one end) 42, another end 43 (the other end 43), and a vertex 41 in a cross section perpendicular to the main surface of the substrate 8. The end 42 and the other end 43 of the curved surface 40 in the cross section may be, in the curved surface 40 constituting the upper surface of the lens 17, the vertex of a portion having a convex shape in a direction toward the substrate 8 in the peripheral portion of the lens 17. The vertex in this case may be the point at which the gradient of the approximate curve of the curved surface 40 in the cross section becomes zero or may be the vertex of a downward point. In FIGS. 1A and 2, the ends 42 and 43 may be assemblies of points at which the distance from the main surface S1 of the substrate 8 is minimum. Also, they may be assemblies of points at which the angle (lens face angle a) formed by the tangent of the curved surface 40 of the lens 17 and the main surface S1 of the substrate 8 becomes maximum.

The vertex 41 of the curved surface 40 can be defined as the centroid of the face surrounded by the end 42 on the curved surface 40. In the examples of FIGS. 1A, 1B, and 2, it can also be comprehended that the vertex 41 is a portion spaced farthest apart from the main surface S1 of the substrate 8 in the curved surface 40 constituting the upper surface of the lens 17. In contrast, in the example of FIG. 4, the vertex 41 is not a portion spaced farthest apart from the main surface S1 of the substrate 8 in the curved surface 40 constituting the upper surface of the lens 17. FIGS. 1A, 1B, 2, and 4 each show a cross section passing through the vertex 41 of the curved surface 40 constituting the upper surface of the lens 17 and perpendicular to the main surface S1 of the substrate 8.

In the examples of FIGS. 1A, 1B, 2, and 4, the straight line L1 (first straight line) is a line passing through both ends (end 42 and end 43) of the lens 17, and the straight line L2 (second straight line) is a line extending in a direction perpendicular to the straight line L1 and passing through the vertex 41 of the lens 17.

FIGS. 1A, 2, and 4 show examples in which the curved surface 40 of the lens 17 is a part of a spherical surface and is symmetrical with respect to the symmetry axis passing through the vertex 41 in the cross section. The symmetry herein allows for variations equivalent to manufacturing errors. In contrast, in FIG. 1B, the curved surface 40 of the lens 17 is a part of an aspherical surface and is not symmetrical with respect to a line passing through the vertex.

In another viewpoint, in the examples shown in FIGS. 1A, 1B, and 2, in a cross section, the tangent at the vertex 41 of the curved surface 40 is parallel to the main surface S1 of the substrate. The straight line L2 is approximately perpendicular to the main surface of the substrate 8. In contrast, in the example of FIG. 4, in a cross section, the tangent at the vertex 41 of the curved surface 40 is not parallel to the main surface S1 of the substrate. The straight line L2 is not perpendicular to the main surface of the substrate 8 and has an inclination angle.

The effects of the present embodiments will be described using FIGS. 1A, 1B, and 2 to 4. The angle formed by a beam of light emitted from the light-emission portion 32 and a perpendicular line with respect to the emission face of the light-emission portion 32 is defined as an emission angle. The angle formed by a beam of light emitted from the lens 17 and a perpendicular line with respect to the main surface of the substrate 8 is defined as an extraction angle β.

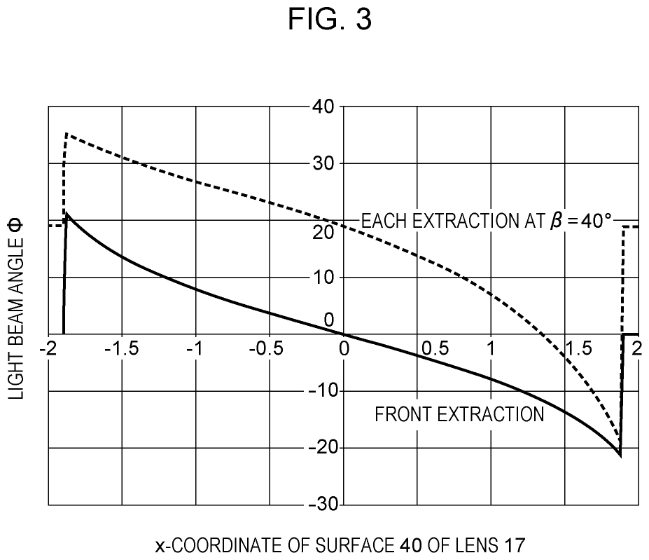

FIG. 3 shows positions of the curved surface 40 of the lens 17 and beam angles Φ of light passing through the positions when the extraction angle β is 0 degrees (when light emitted to the front is extracted) and when the extraction angle β is 40 degrees (when light is extracted so that the extraction angle β shown in FIGS. 1A, 1B, and 2 is 40 degrees). In FIG. 3, the horizontal axis represents the X-coordinate of the curved surface 40 of the lens 17, and the vertical axis represents the beam angle Φ. Here, in FIGS. 1A, 1B, and 2 to 4, the coordinate in a direction parallel to the main surface of the substrate 8 is defined as the X-coordinate.

The emission intensity of light emitted from the light-emission portion 32 varies depending on the beam angle Φ. For example, as described below, in an organic light-emitting device having an optical resonator structure, since the interference conditions change depending on the emission angle from the light-emission portion, light with a large emission angle may have a small emission intensity. That is, since the proportion of light with a large emission angle (i.e., a small emission intensity) increases as the extraction angle β increases, the intensity of extracted light may decrease. Accordingly, when the beam angle Φ is 0 degrees (front extraction), the emission intensity is the highest, and the intensity of emission light may decrease as the beam angle Φ increases (extraction becomes in a diagonal direction). The light-emitting apparatus shown in FIG. 3 has such characteristics.

On this occasion, as obvious from FIG. 3, when the extraction angle β is 0 degrees, at the position of 0 in the X-coordinate, the beam angle Φ is 0 degrees, and in the light emitted from the light-emission portion 32, the brightest light is extracted. As the X-coordinate of the position of the curved surface 40 of the lens 17 departs from 0, the beam angle Φ also departs from 0 degrees. That is, the emission intensity of light decreases.

When the extraction angle β is 40 degrees, the value of the beam angle Φ is approximately 19 degrees at also the position where the X-coordinate is 0, and it is inferred that the emission intensity of light becomes lower than that when the extraction angle β is 0 degrees. In the region where the X-coordinate of the curved surface 40 of the lens 17 is negative 2, the value of the beam angle Φ is 20 degrees or more, which is equivalent to or higher than the value of the beam angle Φ at the largest position on the X-axis where the emission intensity when the extraction angle β is 0 degrees is expected to be the lowest. That is, it is demonstrated that the emission intensity is decreased by increasing the extraction angle β to more than 0 (oblique emission).

Here, the emission angle can be decreased while maintaining the value of the extraction angle β by inclining the reflective layer 9 so as to forward the vertex 41 of the lens 17. The emission angle for giving a beam angle Φ can be decreased by an inclination angle θ by inclining the reflective layer 9 by the inclination angle θ when light is emitted from the light-emission portion 32. In this case, in the graph shown in FIG. 3, the line of an extraction angle of 40 degrees moves to the side of the line of an extraction angle of θ degrees. Accordingly, in FIG. 3, in a large emission angle range emitting from a position of the surface 40 of the lens 17 corresponding to the position with a large negative value on the X-coordinate, the emission angle can be decreased.

Accordingly, in the configurations shown in FIGS. 1A and 1B in which the reflective layer 9 includes an incline portion with an inclination angle θ, the emission intensity of light emitted from the lens 17 is higher than that in the configuration of a comparative example shown in FIG. 2 in which the reflective layer is not inclined with respect to the main surface of the substrate 8.

That is, as shown in FIGS. 1A and 1B, when the reflective layer 9 includes an incline portion forming a positive inclination angle θ in a direction toward the vertex of the lens, the emission angle of light refracted and extracted in the region to the left of the vertex 41 of the lens 17 can be decreased when light is extracted, compared to the case not including an incline portion, as shown in FIG. 2, at the same extraction angle β. Consequently, the efficiency of light extraction in a diagonal direction can be improved by a configuration in which the reflective layer 9 includes an incline portion.

The term “a member (face, line) A has an inclination angle with respect to a member (face, line) B” refers to the case where the member (face, line) A is inclined and has an angle with respect to the member (face, line) B and does not include the case where there is no angle between the member A and the member B (0 degrees).

Light with a large emission angle may have a decreased color purity compared to light with a small emission angle. Accordingly, by the above-described effects, the color purity of light extracted in a diagonal direction can be improved by a configuration in which the reflective layer 9 includes an incline portion.

A range of the inclination angle θ₁ will be described with reference to FIGS. 1A, 1B, 2, 4, and 5A to 5C. Here, for simplicity, the case where the refractive indices are uniform from the conductive layer 11 to the lens 17 will be described, but the same can be similarly considered when the refractive indices are different, considering the refraction of light at the interface of each layer.

The inclination angle θ₁ can be appropriately set depending on the extraction angle required for a light-emitting apparatus, and the extraction efficiency of light that is extracted to the wide angle side can be increased by increasing the inclination angle θ₁. At the same time, an increase in the inclination angle θ₁ may make it difficult to control the thicknesses of the organic layer 20 and the conductive layer 11 that are formed thereon. In addition, an increase in the inclination angle θ₁ improves the light-extraction efficiency in a diagonal direction but may decrease the light-extraction efficiency in a front direction. Accordingly, from the viewpoint of simplifying the process of forming the organic layer 20 and the conductive layer 11, the inclination angle θ₁ can be decreased.

As described above, when the light-emitting apparatus is used as a display apparatus such as a head mount display, the extraction efficiency in a diagonal direction can be increased in a peripheral portion of a region where a plurality of light-emitting devices are arranged (display region). In contrast, in the center area of the display region, the extraction sufficiency in a front direction may be increased. Accordingly, as described later, the inclination angle θ₁ can be decreased from the viewpoint of suppressing a decrease in the extraction efficiency in a front direction in the center area of the display region in a configuration in which reflective layers 9 with the same shape are formed in the whole display region.

As described above, it is necessary to set the inclination angle θ₁ in an appropriate range. The case where the intensity of light that is emitted from the light-emission portion 32 and is refracted at the vertex 41 of the lens 17 and extracted at an angle β is improved will be examined. As shown in FIG. 1A, when the refraction of a beam is traced from the light-extraction side, the beam arrives at the incline portion 21.

On this occasion, when the beam angle in the lens is defined as beam angle Φ, the emission angle is |Φ−θ₁|. Accordingly, when the inclination angle θ₁ and the beam angle Φ coincide with each other, the emission angle becomes 0, and the intensity of light refracted at the vertex 41 of the lens 17 and extracted at an angle β can be maximum.

Here, when the inclination angle θ₁ is larger than the beam angle Φ, which works to increase the emission angle of the light refracted in the region to the right of the vertex 41 of the lens 17 (negative X-coordinate) in FIG. 1A and extracted at an angle β. Accordingly, as the entire light extracted at the angle β, the extraction efficiency is decreased compared to the case where the inclination angle θ₁ and the beam angle Φ coincide with each other.

In addition, as described above, from the viewpoint of simplifying the process of forming the organic layer 20 and the conductive layer 11, the inclination angle θ₁ can be decreased. Accordingly, the inclination angle θ₁ can be set within a range not exceeding “beam angle Q=inclination angle θ₁” where the extraction efficiency in a diagonal direction is maximum, that is, can be set within a range of “inclination angle θ₁≤beam angle Φ”.

In a cross section, the point spaced farthest apart from the vertex 41 of the lens 17 in a direction parallel to the main surface of the substrate 8 in the face of the incline portion on the lens 17 side is defined as a first position P1. On this occasion, when the distance between the vertex 41 and the first position P1 in the parallel direction and the distance in the perpendicular direction are defined as distance H₁ and distance V1, respectively, in order to satisfy inclination angle θ₁≤beam angle Φ, a relationship of tan θ₁<H₁/V₁ may be satisfied.

Accordingly, as described so far, since the emission angle can be decreased by satisfying the relationship of tan θ₁<H₁/V₁, the efficiency of light extraction in a diagonal direction can be improved.

In another viewpoint, the condition of incident angle θ₁≤beam angle Φ can be satisfied by the following configuration. In examples of FIGS. 1A and 1B, the configuration may be such that the intersection point P0 of the straight line L2, which is perpendicular to a straight line L1 (which passes through both ends (end 42 and end 43) of the lens) and which passes through the vertex 41, and the normal line at the point P1 of the incline portion 21 coincide with the vertex 41 of the lens or is to the light-extraction side of the vertex 41. Here, the point P1 is the farthest point from the vertex 41 of the lens 17 in the incline portion 21 in a direction parallel to the main surface of the substrate 8.

The configuration may be such that in a cross section, the intersection point of the straight line L2, which is perpendicular to the straight line L1 (which passes through both ends (end 42 and end 43) of the lens) and which passes through the vertex 41, and the normal line at a point on the incline portion 21 coincides with the vertex 41 of the lens or is to the light-extraction side of the vertex 41. The efficiency of light extraction in a diagonal direction can be improved by setting such that the intersection point P0 of the normal line at the point P1 (first position) and the symmetry axis L2 of the lens coincides with the vertex 41 of the lens or is located on the light-extraction side of the vertex 41. In addition, regarding to an intended extraction angle β, θ₁ can be set with respect to any position in the incline portion 21 based on the approach described above.

Even in the case where the incline portion 21 is curved as described later, the efficiency of light extraction in a diagonal direction can be improved by a configuration in which a relationship of tan θ₁<H₁/V₁ is satisfied at the point where the inclination angle is maximum in the incline portion 21. The efficiency of light extraction in a diagonal direction can be improved by configuring such that the intersection point P0 of the normal line L3 at the incline portion and the symmetry axis L2 of the lens coincides with the vertex 41 of the lens or is present in (located to) the light-extraction side of the vertex 41.

In the comparative example shown in FIG. 4, the straight line L2 that passes through the vertex 41 of the lens 17 and extends in a direction perpendicular to a straight line passing through both ends of the lens (end 42 and end 43) is not perpendicular to the main surface of the substrate 8, and the straight line L2 and the normal line of the incline portion are parallel to each other. In this configuration example, high intense light emitted from the incline portion 21 at an emission angle of zero is not refracted at the vertex 41 of the lens 17 and is extracted at the same emission angle, resulting in an insufficient effect of intensifying the light in a diagonal direction. In the examples of the present embodiments shown in FIGS. 1A and 1B, since the light emitted from the incline portion 21 at an emission angle of zero can be refracted to a further wide angle at the vertex 41 of the lens 17, it is possible to cause an effect of intensifying the light in a diagonal direction.

More specifically, in the examples of the present embodiments shown in FIGS. 1A and 1B and the comparative example shown in FIG. 4, the case where the reflective layer 9 has the same inclination angle θ₁ will be described. In the comparative example of FIG. 4, the light emitted from the incline portion at an emission angle of zero and transmitted through the vertex 41 of the lens 17 is perpendicular to the tangent of the curved surface of the lens 17 at the vertex 41, is not refracted, and is extracted directly into the air at an extraction angle β that is equal to the inclination angle θ₁.

In contrast, in the examples of the present embodiment shown in FIGS. 1A and 1B, when the refractive index of the lens 17 and the medium layer is defined as n₂, the light emitted from the incline portion 21 at an emission angle of zero is refracted at the vertex 41 of the lens at an angle such that the extraction angle β is sin⁻¹(n₂·sinθ₁) and can be extracted on a wider angle side. Also, at points other than the vertex 41 of the curved surface 40 of the lens 17, the configurations shown in FIGS. 1A and 1B similarly cause the effect of refracting to a wider angle side. Accordingly, compared to the example of FIG. 4, the configurations shown in FIGS. 1A and 1B can enhance the efficiency of extraction in a diagonal direction when the inclination angles θ₁ are equivalent.

A relationship between the inclination angle θ₁ and the refractive index n₁ of the medium layer will be described. Light that is refracted at the vertex 41 of the lens 17 is considered. When conditions for extracting the light of a beam angle Φ₀ in the lens 17 without causing total reflection are considered, the refractive index n₂ of the lens 17 satisfies sin Φ₀<1/n₂. That is, the light of an angle of Φ₀ or more in the lens is totally reflected in the region on the right side of the vertex 41 of the lens 17 and is therefore not extracted to the outside.

Conditions of the angle Φ₁ of a beam in the medium layer for being extracted without causing total reflection are, according to Snell's law, sin Φ₂<1/n₁, where n₁ is the refractive index of the medium layer. The inclination angle θ₁ can be set to intensify the intended extraction angle, but since a condition for extracting light emitted at an emission angle of 0 from the incline portion 21 with an inclination angle θ₁ without being totally reflected at the vertex 41 of the lens 17 is θ₁<Φ₂, it may be sin θ₁<1/n₁ from the viewpoint of improving the light-extraction efficiency.

The medium layer may be composed of a plurality of layers and may have multiple functions. For example, the medium layer may include a protection layer, a color-filter layer, a planarization layer, and so on. When the medium layer is composed of a plurality of layers, the refractive index of the layer that is in contact with the conductive layer (second electrode) 11 may be used as the refractive index n₁ of the medium layer.

A range of the distance H₁ between the vertex 41 of the lens 17 and the first position P1 in a direction parallel to the main surface of the substrate 8 will be described. When the light that is emitted from the first position P1 and that is refracted at and extracted from the vertex 41 of the lens is considered, the larger the distance H₁, the larger the extraction angle β can be by the refraction. Accordingly, the extraction efficiency in a diagonal direction is improved.

In contrast, when the distance H₁ is greater than V₁/(n₂²−1)^{1/2}, where n₂ is the refractive index of the lens 17, the light emitted from the first position P1 that arrives at the vertex 41 of the lens is totally reflected. Accordingly, the efficiency of extraction in a diagonal direction can be improved within a range of 0<H₁<V₁/(n₂²−1)^{1/2}. The distance “a” between the center C1 of the light-emission portion and the first position P1 in a horizontal direction may be set within a range of a<H₁<V₁/(n₂²−1)^{1/2}.

A shape of the curved surface 40 of the lens 17 in the present embodiments will be described. As described above, since the deviation in interference conditions becomes greater as the emission angle range of the extracted light in the light-emission portion 32 broadens, the emission intensity decreases, which may become a factor of decreasing the extraction efficiency. That is, in the present embodiments, in order to enhance the extraction efficiency to an intended extraction angle β, the range of the emission angle, in the light-emission portion 32, of the light refracted at the curved surface 40 of the lens 17 and extracted at an angle β can be narrow.

When the light refracted at the curved surface 40 of the lens 17 from a direction (front direction) perpendicular to the main surface of the substrate 8 on the light-extraction side is considered, considering the point where the light is focused as the focal point, a decrease in the range of the emission angle can be rephrased as an increase in the distance from the focal position to the lens 17. Accordingly, the focal position can be set at a position spaced apart from the light-extraction side; in particular, the focal position may be a position farther from the light-extraction side than the first position P1. The range of the emission angle can be decreased by setting the focal position at a position farther from the light-extraction side than the first position P1, and the extraction efficiency can be improved.

When two beams of light transmitting through the vertex 41 and the end 42 of the lens 17 and emitted in the front direction on the light-extraction side are followed from the light emission side to the vertex 41 and the end 42, the focal position can be defined as a position where two beams intersect each other. The angle (lens face angle a) formed by the tangent of the lens 17 and the main surface of the substrate 8 at the end 42 of the curved surface 40 can be a maximum on the curved surface 40.

The distance from the vertex 41 to the end 42 of a lens 17 in the horizontal direction is defined as H₁, and the distance from the first position P1 to the end 42 in a perpendicular direction is defined as V₂. When a beam that transmits through the end 42 (the second position) and that is emitted in a direction perpendicular to the main surface of the substrate 8 is traced in a direction from the end 42 (the second position) to the light-emission portion 32, the distance traveled by the beam in a direction horizontal to the main surface of the substrate 8, when the beam travels a distance V₂ from the end 42 in a direction perpendicular to the main surface of the substrate 8. That is, in a beam that transmits through the end 42 (the second position) and that is emitted in a direction perpendicular to the main surface of the substrate 8, the distance of the position, spaced apart from the end 42 (the second position) by a distance V₂ in the direction perpendicular to the main surface, from the end 42 (the second position) in the direction parallel to the main surface is defined as A.

In this case, the focal position can be a position farther from the light-extraction side than the first position P1 by satisfying a relationship of A<H₂. Accordingly, the extraction efficiency in a diagonal direction can be improved by satisfying the relationship of A<H₂.

A method for determining the distance A when the medium layer is composed of a plurality of layers having different refractive indices will be described. The distance A can be roughly determined by calculating the angle of a beam in each layer considering the refraction at the interface of each layer. Specifically, when the lens face angle at the end 42 is defined as a, the incident angle of light in a front direction to the end 42 is α. According to Snell's law, the refraction angle γ can be described according to the following relationship: n2·sin γ=n0·sin α, which uses the refractive index n0 of the layer (here, the air) that is in contact with the lens 17 on the light-extraction side and the refractive index n2 of the lens 17.

The angle β1 with respect to a front direction inside the lens 17 is determined, using this refraction angle γ, by β1=|α−γ|. When the medium is composed of N layers including the layer of the lens 17, the layer of the lens 17 is defined as the first layer, and the refractive index of the i′th layer therefrom toward the substrate 8 is defined as ni, the beam angle βi in the i′th layer can be described according to the following equation:

$$ni \cdot sin β i = n 1 \cdot sin β1 .$$

The distance Ai traveled by a beam in a direction parallel to the main surface S1 of the substrate 8 in each layer is determined by Ai=Ti·tan βi using the beam angle βi in each layer and the distance (thickness) Ti of each layer in a direction perpendicular to the main surface of the substrate. Since the distance A can be determined by summing up the distance Ai of each layer from i=1 to i=N, the distance A can be roughly described by the following equation:

$$A = T 1 \cdot tan β1 + T 2 \cdot tan β 2 + … + {T}_{N} \cdot tan {β}_{N} .$$

That is, when the medium layer is composed of a plurality of layers with different refractive indices, the light-extraction efficiency in a diagonal direction is improved by satisfying a relationship of A<H₂ using A determined by the above-described equation.

The extraction angle β of a beam that is refracted and extracted at the point on a curved surface where the lens face angle is α is limited to a range of β≤90−α. A point with a large lens face angle α does not contribute to the extraction to a wide angle. Accordingly, the proportion of contribution to light extraction to a wide angle side in the lens 17 is increased by adjusting the lens face angle α to α<90° at the end 42 of the lens, and the light-extraction efficiency in a diagonal direction is improved. The lens face angle a may be less than 70°.

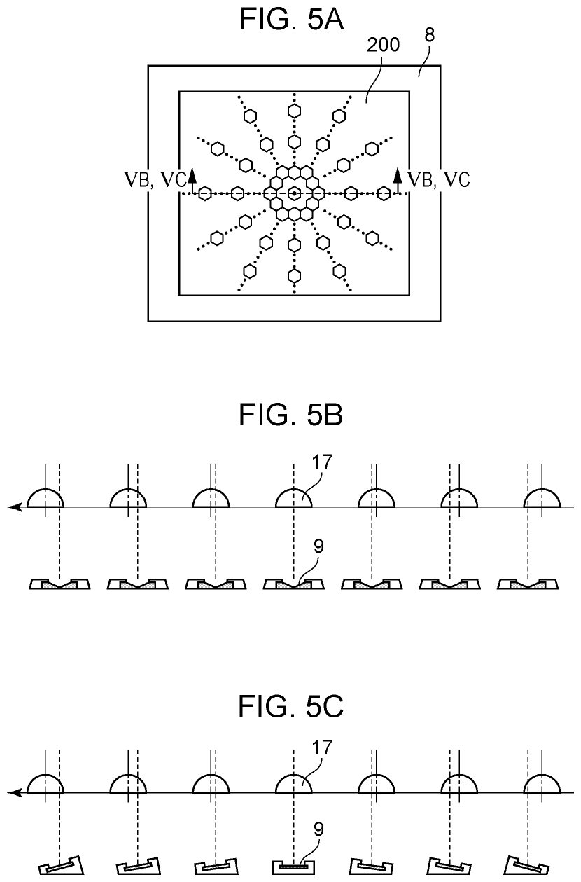

Configuration examples when a plurality of light-emitting devices are arranged will be described with reference to FIGS. 5A to 5C. FIG. 5A is a schematic plan view of a light-emitting apparatus of the present embodiments in which a plurality of light-emitting devices are disposed from a direction perpendicular to the main surface of the substrate 8, FIG. 5B is a cross-sectional schematic view taken along broken line VB-VB in FIG. 5A in one example of the present embodiments, and FIG. 5C is a cross-sectional schematic view taken along broken line VC-VC in FIG. 5A in another example of the present embodiments.

As described above, when the light-emitting apparatus is combined with an optical system and used as a display apparatus, light extracted in a front direction of the substrate is used near the center of the display region 200 where a plurality of light-emitting devices are arranged, and light extracted in a diagonal direction with respect to the substrate 8 may be used in the peripheral portion of the display region. In such a case, as shown in FIGS. 5A to 5C, in the center of the display region 200, the center of the light-emission portion and the vertex of the corresponding lens 17 may be disposed so as to overlap each other in a plan view, and the arrangement may be such that the distance between the center of the light-emission portion and the vertex of the corresponding lens 17 in a direction parallel to the main surface of the substrate 8 is increased with the distance from the center of the display region.

In this occasion, in a plan view, a direction from the center of a light-emission portion toward the vertex of the corresponding lens 17 and a direction from the center of the display region 200 toward the center of the light emission portion are approximately coincide with each other. Similarly, in a plan view, a direction from the center of a light emission portion toward the vertex of the corresponding lens 17 and a direction from the center of a display region 200 toward the vertex of the lens 17 approximately coincide with each other. The reflective layer 9 may have the same shape over the whole area of the display region 200 or may have different shapes according to the positions where the light-emitting devices are arranged in the display region 200.

For example, as shown in FIG. 5B, the reflective layer 9 may be in a conical shape and have the same inclination angle over the whole area of the display region 200. When the reflective layer 9 has the same shape and inclination angle in the whole area of the display region 200, the process for forming the reflective layer 9 is easy, and the uniformity in the thickness between each light-emitting device of the organic layer 20 and the conductive layer 11 formed by lamination on the reflective layer 9 is also improved to simplify the formation process.

In another viewpoint, a set of a first light-emission portion disposed in the peripheral portion of the display region 200 and a first lens 17 is defined as a first set, and a set of a second light-emission portion disposed near the center of the display region 200 and a second lens 17 is defined as a second set. In this case, in a plan view, the distance from the vertex of the lens 17 to the first point of the farthest incline portion in a direction parallel to the main surface of the substrate 8 is defined as distance H₁ or distance H₂, the distance in a perpendicular direction is defined as distance V₁ or distance V₂, and the inclination angle is defined as θ₁ or θ₂.

On this occasion, the example shown in FIG. 5B has the relationships of H₁>H₂, V₁=V₂, and θ₁=θ₂. Accordingly, a relationship of V₂·tan θ₂/H₂>V₁·tan θ₁/H₁ is satisfied. In such a configuration, while maintaining the uniformity in the thickness between each light-emitting device of the organic layer 20 and the conductive layer 11, the refraction at the lens 17 is more effectively used in the more-peripheral areas of the display region 200, and the extraction efficiency to the wide angle side can be enhanced.

In another example, as shown in FIG. 5C, the configuration may be such that the shape of the reflective layer 9 is changed depending on the position in the display region 200 where the light-emitting device is formed. In the example shown in FIG. 5C, the reflective layer 9 is in a flat plate shape, and the inclination angle θ is small near the center of the display region 200 and is increased with the distance from the center of the display region 200. The configuration may be such that no incline portion is present in the center of the display region 200.

In such a configuration, the efficiency of extraction in a radiation angle direction, which is required in each light-emitting device, can be increased. In this example, the distance H₁, distance H₂, distance V1, distance V₂, inclination angle θ₁, and inclination angle θ₂ defined as in the above-described example are in relationships of H₁>H₂, V₁=V₂, and θ₁>0₂. In this case, the relationship may be V₂ tan θ₂/H₂≤V₁·tan θ₁/H₁, and the extraction efficiency in an extraction direction required in each light-emitting device can be optimized by satisfying this relationship.

The display region 200 may include a plurality of regions having different inclination angles θ. In this occasion, the reflective layer 9 of a second region where is farther from the center of the display region 200 than a first region may have a larger inclination angle than the inclination angle of the reflective layer 9 of the first region. In such a configuration, while maintaining the uniformity of the thickness between each light-emitting device of the organic layer 20 and the conductive layer 11, the refraction at the lens is more effectively used in the more-peripheral areas of the display region 200, and the extraction efficiency to the wide angle side can be enhanced.

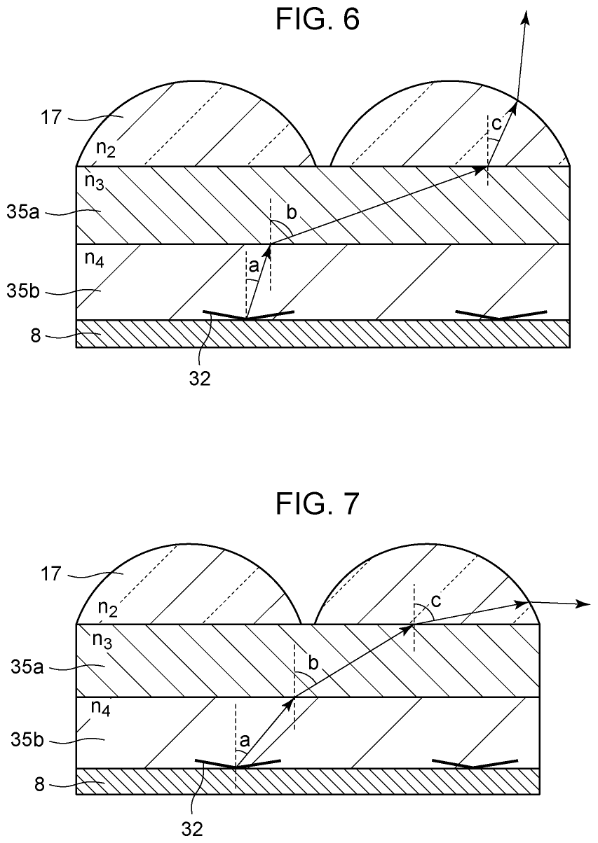

A range of the refractive index of a medium layer having a refractive index different from that of the lens 17 when the medium layer is disposed between the light-emission portion 32 and the lens 17 will be described using FIGS. 6 and 7. FIGS. 6 and 7 are diagrams illustrating configuration examples when medium layers 35a and 35b having different refractive indices are disposed between the light-emission portion 32 and the lens 17. Here, the refractive index of the lens 17 is defined as n₂, the refractive index of the medium layer 35a is defined as n₃, and the refractive index of the medium layer 35b is defined as n₄. For example, the medium layer 35a may be a color filter (color-filter layer 15). For example, the medium layer 35b may be a protection layer 13.

In the configuration shown in FIG. 6, the magnitude correlation of the refractive indices is n₃<n₂<n₄. Considering the refraction of beams emitted from the light-emission portion 32 in a diagonal direction, the magnitude correlation of angles a, b, and c is a<c<b according to the magnitude correlation of the refractive indices. Here, when c<b, a beam is bent at the interface between the medium layer 35a and the lens 17 in a direction closer to the front.

Accordingly, as shown in FIG. 6, light emitted from the light-emission portion 32 may be emitted from the lens 17 of the adjacent light-emitting device to a direction close to the front. Accordingly, there is a risk of causing crosstalk between light-emitting devices, which may reduce the image quality. In addition, the radiation angle from the light-emission portion 32 is large, and light with low color purity easy to visually recognize. Therefore, there is a risk of a reduction in the color purity.

In contrast, in the configuration shown in FIG. 7, the magnitude correlation of the refractive indices is n₂<n₃<n₄. Accordingly, the magnitude correlation of angles a, b, and c is a<b<c. The light emitted from the light-emission portion 32 in a diagonal direction is refracted to a wider angle side at the interface between the medium layer 35a and the lens 17, and is hardly emitted in the front direction. Accordingly, a reduction in the color purity can be suppressed.

As described above, crosstalk between light-emitting devices and a decrease in the color purity can be suppressed by a configuration in which a layer having a refractive index smaller than the refractive index n₁ of the lens 17 is not disposed between the light-emission portion 32 and the lens 17. For example, in the configuration shown in FIG. 7, the refractive index n₂ of the lens 17 and the refractive index n₃ of the medium layer 35a may satisfy a relationship of n₂≤n₃. The refractive index n₄ of the medium layer 35b disposed between the medium layer 35a and the light-emission portion 32 may satisfy a relationship of n₂≤n₄. Furthermore, the refractive index n₄ of the medium layer 35b may satisfy a relationship of n₃≤n₄.

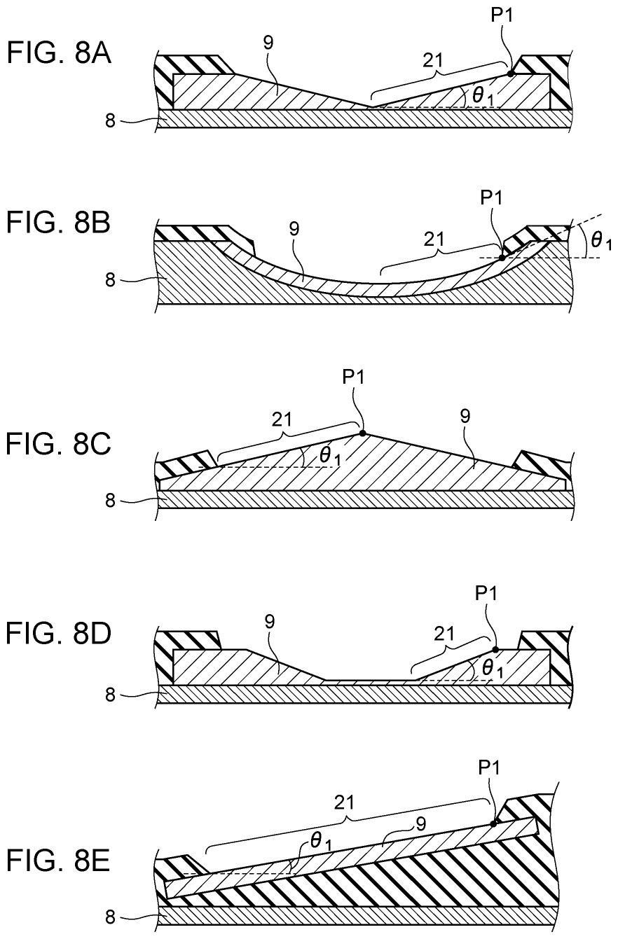

Examples of the shape of the reflective layer 9 of the present embodiments will be described with reference to FIGS. 8A to 8E. FIG. 8A is a schematic diagram showing the reflective layer 9 in the configuration example of FIGS. 1A and 1B and parts relating thereto. FIGS. 8B to 8E are schematic diagrams showing other reflective layers 9 and parts relating thereto in other configuration examples of the present embodiments. In the examples shown in FIGS. 8A to 8E, the incline portion 21, first position P1, and inclination angle θ₁ are shown when the vertex of a lens is shifted to the left direction with respect to the center of the light-emission portion. As described above, the reflective layer 9 includes an incline portion 21 in a direction toward the vertex of the lens. The emission angle from the light-emission portion can be decreased by this inclination. As described above, the light-extraction efficiency is improved, and light with high color purity can be extracted. Hereinafter, as shown FIGS. 8A to 8E, the inclination angle θ₁ of the tangent to the reflection surface (the surface of the reflection layer 9) at the first position P1 with respect to the main surface S1 of the substrate 8 is defined as a positive value (0°<θ₁<90°) in a direction toward the vertex of a lens.

The reflective layer 9 needs only to have a reflection surface that is inclined in a direction toward the lens vertex with respect to the main surface S1 of the substrate 8 on the light-extraction side, and as in the examples of FIGS. 8A and 8C, may have an inclination in the opposite direction with the center of the light-emission portion as the boundary. In addition, as the example of FIG. 8B, the inclination angle θ₁ may continuously change, and the inclination may be zero at the center of the light-emission portion. As in the example of FIG. 8E, the inclination angle θ₁ may be constant, or as in the example of FIG. 8D, there may be a region with no inclination.

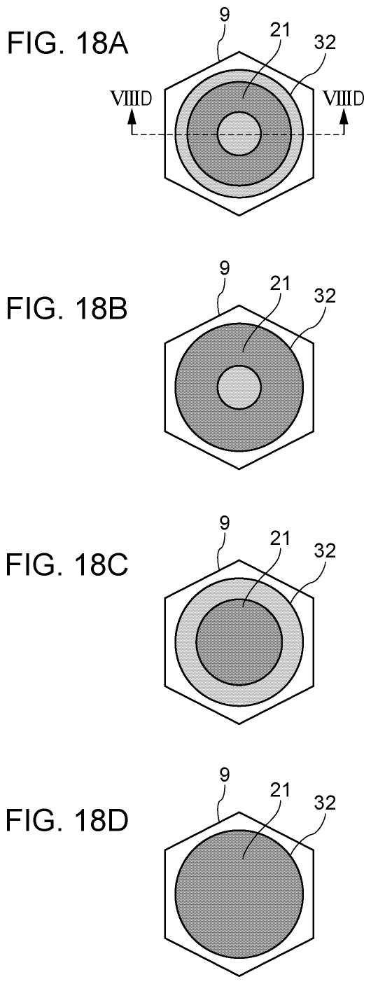

Examples of the planar shape, in orthographic projection to the main surface of the substrate 8, of the reflective layer 9, light-emission portion 32, and incline portion 21 in the present embodiments will be described with reference to FIGS. 18A to 18D. FIG. 18A is a schematic view illustrating a planar shape of the configuration example of FIG. 8D. FIG. 8D is a cross-sectional view taken along line VIIID-VIIID in FIG. 18A. FIGS. 18B to 18D are schematic views of planar shapes of the reflective layer 9, light-emission portion 32, and incline portion 21 in other configuration examples of the present embodiments.

The planar shape of the reflective layer 9 in the examples shown in FIGS. 18A to 18D is a hexagon, but is not limited thereto, and may be a polygon (such as a quadrangle), a circle, or an ellipse. For the purpose of simplifying the design, the planar shape may be a polygon similar to the subpixel shape corresponding to a pixel array described later such that the distance between adjacent reflective layers is constant. For example, when the pixel array is a delta array, the planar shape of the reflective layer 9 may be a hexagon.

In the first electrode (reflective layer 9) of a light-emitting device, the exposed area not covered with the insulation layer 12 is the light-emission portion 32. The planar shape of the light-emission portion 32 is a circle in the examples shown in FIGS. 18A to 18D, but is not limited thereto, and may be a polygon, such as a quadrangle and a hexagon, or an ellipse. Also, the planar shape may be a shape such as a ring surrounded by two figures. The two figures may be circles, polygons, or ellipses and may be similar figures or different types of dissimilar figures. From the viewpoint of enhancing the symmetry of radiation angle characteristics, the planar shape of the light-emission portion 32 can have high symmetry. In this viewpoint, the planar shape may be a regular polygon or a circle.

FIGS. 18A to 18D illustrate regions that can function as the incline portion 21. The reflective layer 9 is inclined with respect to the main surface of the substrate, and the region overlapping the light-emission portion 32 in an orthographic projection to the main surface of the substrate can function as the incline portion 21. In the light-emission portion 32, the reflective layer 9 in the region other than the region that can function as the incline portion 21 may be parallel to the main surface of the substrate. The outer edge of the region that can function as the incline portion 21 and the outer edge of the light-emission portion 32 do not coincide with each other in the example shown in FIG. 18A and coincide with each other in the example shown in FIG. 18B.

Since the light extracted in a diagonal direction is radiated from a region near the outer edge of the light-emission portion 32 in a large proportion, the effect of improving the efficiency of light extraction in a diagonal direction is enhanced by having the incline portion 21 in the region near the outer edge. Accordingly, from the viewpoint of improving the efficiency of light extraction in a diagonal direction, the outer edge other than the region that can function as the incline portion 21 and the outer edge of the light-emission portion 32 may coincide with each other.

In the examples shown in FIGS. 18C and 18D, the planar shape of the region that can function as the incline portion 21 is a circle. FIG. 18C shows an example in which the outer edge of the region that can function as the incline portion 21 and the outer edge of the light-emission portion 32 do not coincide with each other. FIG. 18D shows an example in which the outer edge of the region that can function as the incline portion 21 and the outer edge of the light-emission portion 32 coincide with each other.

FIG. 18D corresponds to the examples shown in FIGS. 8A to 8C and 8E. The planar shape of the region that can function as the incline portion 21 is not limited to a ring and a circle, and the planar shape of the region may be a polygon, an ellipse, or a shape surround by two polygons or ellipses. From the viewpoint of enhancing the symmetry of the radiation angle characteristics, the planar shape of the region that can function as the incline portion 21 may be a similar shape to the planar shape of the light-emission portion 32 or may be a shape surrounded by two figures that are similar to the planar shape of the light-emission portion 32. Accordingly, when the light-emission portion 32 is circular, the planar shape of the region that can function as the incline portion 21 may be a circle or an ellipse.

In the light-emission portion 32, the proportion of the area occupied by the region that can function as the incline portion 21 may be appropriately set within a range of greater than 0% and 100% or less from the balance of the efficiency of light extraction in a front direction and a diagonal direction, and may be 50% or more from the viewpoint of improving the efficiency of light extraction in a diagonal direction. When a plurality of subpixels that emit different colors are disposed, for the purpose of reducing the difference in the chromaticity in a front direction and a diagonal direction, the proportion of the area occupied by the incline portion in the light-emission portion 32 may be different for each subpixel.

As a method for forming the incline portion of the reflective layer 9, a reflective layer is formed on a flat substrate 8 or on an insulation layer having a flat upper surface disposed on a substrate, and a shape having an incline portion can be then formed by combining photolithography and etching. Also, the incline portion of the reflective layer 9 can be formed by forming an incline portion in an insulation film laminated on a substrate 8 in advance using photolithography and etching and then forming a reflective layer along its shape.

More specifically, a photoresist layer with different thicknesses is formed on a reflective layer 9 having an upper surface parallel to a main surface of a substrate, and etch-back is then performed to form an incline portion. The photoresist layer with different thicknesses can be formed by exposure using an area-gradation mask. Also, a photoresist layer with different thicknesses can be formed on an insulation film laminated on a substrate 8, and etch-back is then performed to form an insulation film having an incline portion. FIGS. 8A, 8B, and 8D are configuration examples using a reflective layer 9 having an upper surface parallel to a main surface of a substrate, and FIGS. 8C and 8E are configuration examples in which an incline portion is formed in advance in an insulation film on a substrate. A more specific configuration example of the light-emitting apparatus will be described. The light-emitting apparatus can include a substrate 8, a reflective layer (first electrode) 9, an organic layer 20, a conductive layer (second electrode) 11, an insulation layer 12, a protection layer 13, a planarization layer, a color filter 15, a planarization layer, and a lens 17. In this configuration example, the reflective layer 9 and the conductive layer 11 function as a first electrode and a second electrode, respectively. The reflective layer 9 as the first electrode is disposed on the substrate 8. The reflective layer 9 as the first electrode can also be called a lower electrode.

The organic layer 20 includes a light-emission layer containing a light-emitting material. A part of the organic layer 20 (light-emission layer) functions as the above-described light-emission portion 32. The organic layer 20 is disposed between the substrate 8 and the lens 17 so as to cover the reflective layer 9 as the first electrode. The conductive layer 11 as the second electrode is disposed on the organic layer 20. The conductive layer 11 as the second electrode can also be called an upper electrode. The organic layer 20 (light-emission layer) emits light by a difference in the electric potential between the first electrode (reflective layer 9) and the second electrode (conductive layer 11).

The insulation layer 12 is disposed between adjacent first electrodes (reflective layers 9) such that the adjacent first electrodes (reflective layers 9) are insulated from each other. The insulation layer 12 can also be called a bank. The insulation layer 12 is disposed in an outer edge portion on the first electrode (reflective layer 9). The exposed area of the first electrode (reflective layer 9) not covered with the insulation layer 12 is in contact with the organic layer 20. The area of the organic layer 20 being in contact with the first electrode (reflective layer 9) can be the above-described light-emission portion 32. Accordingly, in the light-emitting apparatus, a plurality of light-emission portions 32 respectively corresponding to a plurality of first electrodes (reflective layers 9) can be disposed.

The protection layer 13 is disposed on the second electrode (conductive layer 11), and the planarization layer is disposed on the protection layer 13. Color filters 15 can be disposed on a planarization layer so as to respectively correspond to a plurality of light-emission portions 32. A planarization layer is disposed on the color filters 15. Lenses 17 are disposed on the planarization layer. The lenses 17 are disposed so as to respectively correspond to the plurality of light-emission portions 32.

The material that is used as the substrate 8 is not particularly limited as long as it can support the components of the light-emitting apparatus, such as the first electrode (reflective layer 9), the organic layer 20, and the second electrode (conductive layer 11). For example, as the material of the substrate 8, glass, plastic, silicon, and so on may be used. A switching element such as a transistor, a wiring pattern, an interlayer insulation film, or the like may be disposed on the substrate 8.

The first electrode (reflective layer 9) may be transparent or may be opaque. When the first electrode (reflective layer 9) is opaque, the material of the first electrode (reflective layer 9) may be a metal material having a reflectance of 70% or more for the wavelength of light emitted from the light-emission portion 32. For example, as the material of the first electrode (reflective layer 9), a metal such as Al and Ag or an alloy made by adding Si, Cu, Ni, Nd, or the like to Al or Ag may be used. The first electrode may a transparent electrode such as ITO, IZO, AZO, or IGZO, and in such a case, a first electrode and a reflective layer 9 may be laminated.

When a transparent first electrode and a reflective layer 9 are laminated and formed as different layers, the first electrode is formed along the reflective layer 9, and the upper surface of the first electrode and the upper surface of the reflective layer 9 may or may not be parallel to each other. In order to make the optical distance described later uniform in the light-emission portion 32, the upper surface of the first electrode and the upper surface of the reflective layer 9 can be parallel to each other. The first electrode and the reflective layer 9 may or may not be electrically connected to each other.

When the first electrode and the reflective layer 9 are not electrically connected to each other, a transparent insulation layer may be disposed between the first electrode and the reflective layer 9. The material constituting the transparent insulation layer may be, for example, an inorganic material such as silicon oxide and silicon nitride. Even when the first electrode and the reflective layer 9 are electrically connected to each other, in the orthographic projection to the main surface of the substrate 8, a transparent insulation layer is disposed between the first electrode and the reflective layer 9 in the region of the light-emission portion 32, and the first electrode and the reflective layer 9 may be electrically connected to each other in the region outside the light-emission portion 32.

When the first electrode and the reflective layer 9 are electrically connected to each other, the first electrode and the reflective layer 9 may be directly connected, may be connected through another conductive layer, or may be connected through an element such as a transistor.

The first electrode (reflective layer 9) may be a layered electrode with a barrier electrode such as a metal such as Ti, W, Mo, and Au or its alloy or may be a layered electrode with a transparent oxide film electrode such as ITO and IZO, as long as a required reflectance is obtained. In order to optimize the optical distance described later, the reflective layer 9 as the first electrode may adopt a configuration in which an insulation film is provided between the reflective layer and a transparent conductive film.

The second electrode (conductive layer 11) may be a semitransparent electrode having properties of transmitting some light arrived at the conductive layer 11 and reflecting other light (that is, translucent reflectivity). As the material for the second electrode (conductive layer 11), for example, a transparent material such as a transparent conductive oxide may be used. As the material for the second electrode (conductive layer 11), a semitransparent material consisting of a single metal (such as Al, Ag, and Au), an alkali metal (such as Li and Cs), an alkaline earth metal (such as Mg, Ca, and Ba), or the like may be used. Also, a semitransparent material consisting of an alloy material containing the above-mentioned metal material may be used.

When a semitransparent material is used as the material for the second electrode (conductive layer 11), an alloy mainly composed of Mg or Ag may be used as the semitransparent material. If the second electrode (conductive layer 11) has appropriate transmittance, the second electrode (conductive layer 11) may have a layered structure of a plurality of layers made of the above-mentioned materials. In the configurations shown in FIGS. 1A and 1B, a second electrode (conductive layer 11) common to a plurality of light-emission portions 32 is provided. However, the configuration is not limited thereto, and a plurality of second electrodes (conductive layers 11) respectively corresponding to the plurality of light-emission portions 32 may be disposed.

One of the first electrode (reflective layer 9) and the second electrode (conductive layer 11) functions as a positive electrode, and the other of the first electrode (reflective layer 9) and the second electrode (conductive layer 11) functions as a negative electrode. For example, in some embodiments, the first electrode functions as a positive electrode, and the second electrode functions as a negative electrode. Also, in some embodiments, the first electrode functions as a negative electrode, and the second electrode functions as a positive electrode.

The organic layer 20 can be formed by known technique, such as a deposition method and a spin-coating method. The organic layer 20 may be composed of a plurality of layers. When the organic layer 20 is an organic compound layer, the organic layer 20 can be configured by including, in addition to the light-emission layer, at least any of a hole-injection layer, a hole-transport layer, an electron-block layer, a hole-block layer, an electron-transport layer, and an electron-injection layer.

The light-emission layer emits light by recombination of a hole injected from the positive electrode and an electron injected from the negative electrode in the light-emission layer. The light-emission layer may be a monolayer or may be a multilayer. For example, when a light-emission layer containing a red light-emitting material, a light-emission layer containing a green light-emitting material, and a light-emission layer containing a blue light-emitting material are combined, light (red light, green light, and blue light) from each light-emission layer are mixed with one another to give white light. Two types of light-emission layers of which the emission colors are complementary colors (for example, a light-emission layer containing a blue light-emitting material and a light-emission layer containing a yellow light-emitting material) may be combined.

In the light-emitting apparatuses shown in FIGS. 1A and 1B, a configuration in which each light-emission portion 32 emits white light and the light is colored by color filters 15 is shown. However, the configuration is not limited thereto. The material contained in the light-emission layer and the configuration of the light-emission layer may be different in each light-emission portion 32 such that the light-emission layer of each light-emission portion 32 emits light of a different color. In such a case, the light-emission layer may be patterned for each light-emission portion 32.

The configuration may be a so-called tandem structure including a plurality of light-emission layers in the organic layer 20 and electric-charge-generation layers provided between the plurality of light-emission layers. In a tandem structure, a plurality of light-emission layers simultaneously emit light, and the light-emission efficiency can be improved.

The light-emitting apparatus includes a reflective layer 9 disposed between the organic layer 20 that includes a light-emission layer and the main surface S1 of the substrate 8, and a conductive layer 11 disposed between the organic layer 20 that includes a light-emission layer and the lens 17. The reflective layer 9 may be the first electrode or may be a metal layer arranged between the first electrode and the substrate 8. The conductive layer 11 may be the second electrode or may be a semitransparent reflective layer disposed between the second electrode and the lens 17 and having a property of transmitting some light that arrives at the conductive layer 11 and reflecting other light (that is, translucent reflectivity).

In order to optimize the optical distance between the first reflection surface, which is the upper surface of the reflective layer 9, and the light-emission region (light-emission position) of the organic layer 20 including a light-emission layer, the following equation (1) may be satisfied. In equation (1), the optical distance Lr is the optical path length (optical distance) from the first reflection surface, which is the upper surface of the reflective layer 9, to the light-emission position of the organic layer 20; the phase shift Φr is the phase shift when light of a wavelength λ is reflected at the first reflection surface; and m is an integer of 0 or more. The thickness between the reflective layer 9 and the organic layer, the thickness of each organic layer, and so on may be optimized such that equation (1) is satisfied.

$$Lr = ( 2 \times m - ( Φ r / π ) ) \times ( λ / 4 ) . \qquad ( 1 )$$

The optical distance Ls from the light-emission position to the second reflection surface, which is the lower surface of the conductive layer 11, may satisfy the following equation (2), where Φs is the phase shift when light of a wavelength of λ is reflected on the second reflection surface, and m′ is an integer of 0 or more.

$$Ls = ( 2 \times {m}^{′} - ( Φ s / π ) ) \times ( λ / 4 ) . \qquad ( 2 )$$

Accordingly, the whole layer interference L from the first reflection surface to the second reflection surface may satisfy the following equation (3), where m is an integer of 0 or more. In equation (3), Φ is the sum of phase shift Φr and phase shift Φs.

$$L = L r + L = ( 2 \times m - Φ / π ) \times ( λ / 4 ) . \qquad ( 3 )$$

Here, in the above equations (1) to (3), the allowable range is about λ/8 or about 20 nm. Since it may be difficult to specify the light-emission position of the organic layer 20, in the above example, the interface of the light-emission layer on the first reflection surface side or the interface on the second reflection surface side is used in place of the light-emission position. Considering the above-mentioned allowable range, even in such substitution, an effect of intensifying light can be obtained.

The protection layer 13, the planarization layer, the color filter 15, and the planarization layer constitute the above-described medium layer. The protection layer 13 is a dielectric layer. The protection layer 13 has a light-transmitting property. Furthermore, the protection layer 13 may include an inorganic material having low permeability for oxygen and moisture from the outside of the light-emitting apparatus. For example, the protection layer 13 may be formed using an inorganic material such as silicon nitride (SiN), silicon oxynitride (SiON), silicon oxide (SiOₓ), aluminum oxide (Al₂O₃), and titanium oxide (TiO₂). In terms of protection performance, the protection layer 13 may be formed of an inorganic material such as SIN, SiON, and Al₂O₃. The protection layer 13 can be formed using a chemical vapor-phase deposition (CVD) method, an atomic layer deposition (ALD) method, a sputtering method, or the like.

The protection layer 13 may have a monolayer structure made of the above-mentioned material or may have a layered structure made of a combination of the above-mentioned materials as long as sufficient moisture insulation performance is obtained. For example, the protection layer 13 may have a layered structure of a layer of silicon nitride formed using a CVD method and another layer with high density (for example, Al₂O₃) formed using an ALD method. Furthermore, the protection layer 13 may include an organic layer as long as it has moisture-insulation performance. In the organic layer, for example, polyacrylate, polyimide, polyester, epoxy, and so on can be used. Furthermore, in the configurations shown in FIGS. 1A and 1B, a protection layer 13 common to a plurality of light-emission portions 32 is provided, but a plurality of protection layers 13 respectively corresponding to the light-emission portions 32 may be disposed.

The lens 17 can be formed by an exposure process and a development process. Specifically, a material layer (for example, a photoresist film) of the lens 17 is formed, and exposure and development of the photoresist film are performed using a mask having continuous gradation changes. As the mask that is used in formation of the lens 17, a gray mask can be used. It is also possible to use an area-gradation mask that enables light irradiation with continuous gradation changes on the image formation surface as a mask used in formation of the lens 17 by changing the density distribution of dots in the light-shielding film below the resolution of the exposure apparatus.

It is possible to adjust the lens shape by performing etch-back for the lens 17 formed by the exposure process and the development process. As described above, the upper surface of the lens 17 only needs to have a curved surface 40 having a light-harvesting property, and the curved surface 40 may be a part of a spherical surface or may be an aspherical surface.

The layer that is in contact with the lens 17 on the light-extraction side may be a gas, such as air, or may be a resin or the like. The layer can have a refractive index lower than that of the lens 17 and may be a resin or the like in which hollow particles are dispersed.

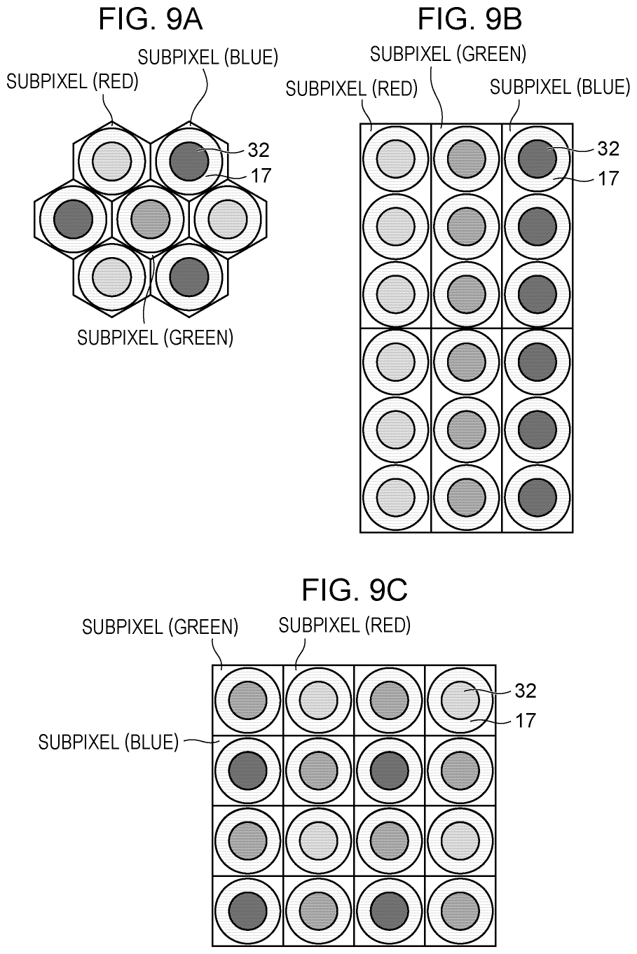

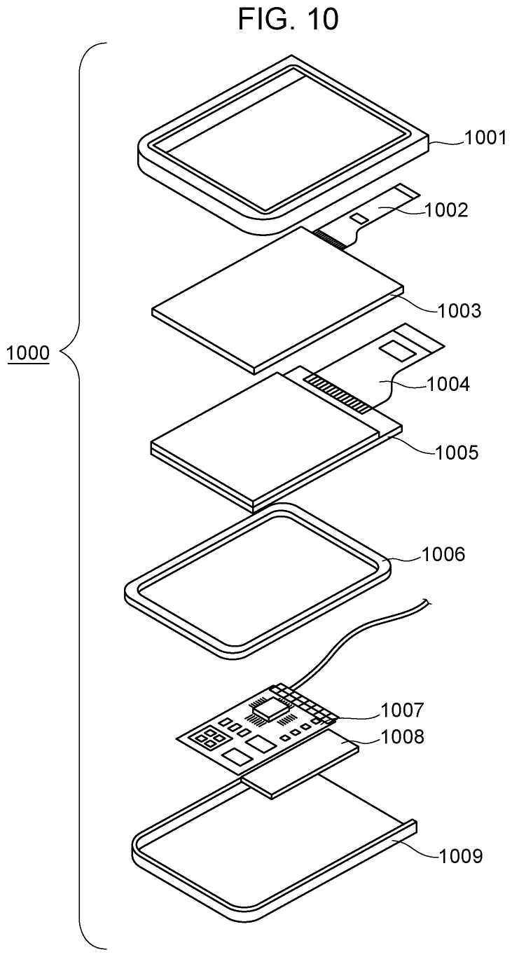

The light-emitting device is configured by combining the light-emission portion 32 and the curved surface 40 of the lens 17 and so on. When a plurality of light-emitting devices are provided, the planar array (array when viewed from the normal direction of the main surface of the substrate 8) of the plurality of light-emitting devices may be any array, such as a stripe array, a square array, a delta array, a pentile array, and a Bayer array. FIGS. 9A to 9C are plan views of light-emitting apparatuses viewed from the side of the lens 17 and show examples of planar array of the plurality of light-emitting devices.

FIG. 9A shows an example of a delta array. FIG. 9B shows an example of a stripe array. FIG. 9C shows an example of a Bayer array. Here, considered is the case where a light-emitting apparatus is used as the display panel and one pixel (main pixel) is configured by including a plurality of subpixels whose corresponding color components are different from one another (e.g., a red display subpixel, a green display subpixel, and a blue display subpixel). In this case, as shown in FIG. 9B, a plurality of light-emitting devices may be provided to one subpixel.

The size, shape, and so on of the curved surface 40 of the lens 17 may be appropriately set depending on the system of the planar array of the plurality of light-emitting devices. For example, when a delta array is adopted, the area of a subpixel occupied by the curved surface 40 of the lens 17 can be set large, and the light-extraction efficiency can be enhanced.

In the configurations shown in FIGS. 9A to 9C, the planar shape of the light-emission portion 32 (shape when viewed from the normal direction of the main surface of the substrate 8) is circular, but the planar shape of the light-emission portion 32 is not limited thereto. The planar shape of the light-emission portion 32 may be, for example, a polygon, such as a quadrangle and a hexagon. However, when the planar shape of the light-emission portion 32 is circular, the inclination angle relationship in a direction from the end of the light-emission portion 32 to the end 42 of the curved surface 40 of the lens 17 is equal in all cross sections obtained by the normal-direction face of the main surface of the substrate 8 passing through the vertex 41 of the curved surface 40. Accordingly, the light-emitting apparatus can be easily designed.

As shown in FIGS. 1A and 1B, the lens 17 may be formed such that the end 42 of the curved surface 40 constituting the upper surface of the lens 17 has a thickness (such that adjacent lenses 17 partially overlap each other). In this case, the ends 42 and 43 of the curved surface 40 can be assemblies of parts where the inclination between adjacent lenses 17 is 0° (parallel to the main surface of the substrate 8).

As described above, a configuration in which light of different colors can be transmitted by the lens 17 may be adopted. In the light-emitting apparatus, full color display is possible. As a method for realizing full color display, a method using a light-emission layer emitting white light and a color filter 15 may be adopted. Since the light-emission layer can be common to a plurality of light-emission portions 32, the process of manufacturing a light-emission layer may be easier than the case in which the light-emission layer is patterned for making each light-emission portion 32 emit a different color.

The light-emission layer may be patterned such that a plurality of light-emission portions 32 emit light of colors different from one another. The optical path length L (optical path lengths Lr or Ls) between the above-described reflective layer and conductive layer may be different for each of the light-emission portions 32 that emit light of colors different from one another.

As described above, for the purpose of enhancing the efficiency of light extraction in a diagonal direction, the light-emission portion 32 and the lens 17 may be disposed with their centers displaced from each other. The light-emission portion 32 and the lens 17 may be disposed so as to be displaced in the same direction in the whole area of the light-emitting apparatus or may be disposed such that the center of the light-emission portion 32 and the center of the lens 17 overlap in the area near the center of the light-emitting apparatus and that the shift between the center of the light-emission portion 32 and the center of the lens increases toward the outside of the light-emitting apparatus. In contrast, the center of the light-emission portion 32 and the center of the lens 17 may overlap in the area near the center of the light-emission region.

In the present embodiments, the color filter 15 is provided on the planarization layer, but may be provided on the protection layer 13. For example, in some embodiments, the planarization layer is not disposed, and the color filter 15 and the protection layer 13 are continuous. For example, the color filter 15 and the protection layer 13 may be united. The color filter 15 of the light-emitting apparatus may be formed by forming the color filter 15 on a supporting substrate other than the substrate 8 and bonding it so as to face the protection layer 13.

The planarization layer is provided for planarizing irregularities of the upper surface of the protection layer 13. The color filter 15 can be formed in accurate alignment with respect to the respective light-emission portions 32 by disposing the planarization layer using a photolithography process. As described above, the color filter 15 can be formed in accurate alignment with respect to the light-emission portion 32 by omitting the planarization layer and uniting the color filter 15 and the protection layer 13 using a photolithography process.

In the configurations shown in FIGS. 1A and 1B, the color filters 15r, 15g, and 15b may be color filters transmitting light of colors different from one another. For example, the color filter 15r may transmit red light, the color filter 15g may transmit green light, and the color filter 15b may transmit blue light. A part or the whole of a plurality of color filters 15 may be omitted. In such a case, full-color display is possible by forming a light-emission layer for each light-emitting device in the organic layer 20 and making the colors of light emitted by the light-emission portion 32 different.

In the present embodiments, the lens 17 is provided on the planarization layer. The planarization layer is provided for planarizing irregularities of the upper surface of the color filter 15. However, the lens 17 may be provided on the color filter 15. In such a case, the planarization layer need not be disposed. The lens 17 and the color filter 15 may be united.

Furthermore, in some embodiments, the color filter 15 and the planarization layer are not disposed, and the lens 17 may be provided on the protection layer 13. For example, the lens 17 and the protection layer 13 may be united. When the lens 17 and the protection layer 13 are united, the distance from the lens 17 to the light-emission portion 32 can be shortened, compared to the case in which the lens 17 is formed on another substrate and is bonded so as to face the protection layer 13. As a result, the solid angle of light entering the lens 17 from the light-emission portion 32 can be broadened, and the light-extraction efficiency is improved.

The curved surface 40 of the lens 17 can be formed in accurate alignment with respect to the light-emission portion 32 by uniting the lens 17 and the protection layer 13. For example, mutual alignment of the light-emission portion 32, the color filter 15, and the lens 17 can be performed with high precision by uniting the color filter 15, the lens 17, and the protection layer 13.

The lamination order of the color filter 15 and the lens 17 can be appropriately selected. In the configurations shown in FIGS. 1A and 1B, the color filter 15 is provided on the lens 17 on the light-emission portion 32 side. In this configuration, light emitted from the light-emission portion 32 passes through the color filter 15 before entering the lens 17. Consequently, light that becomes a factor of decreasing color purity (light from the light-emission portion at a large emission angle) passes through the color filter 15 over a relative long distance. Accordingly, a decrease in the color purity when the light-emitting apparatus is observed from a diagonal direction can be more suppressed.

The light-emitting apparatus may be produced by forming the color filter 15 and the lens 17 on a supporting substrate other than the substrate 8 and bonding it so as to face the substrate 8 having the light-emission portion 32. The degree of freedom in the processing method (for example, temperature) when the color filter 15 and the lens 17 are formed is increased by forming the color filter 15 and the lens 17 separately from the organic layer 20 (light-emission layer), and the degree of freedom in the design of the color filter 15 and the lens 17 can be increased.

The color filter 15 and the lens 17 may be continuously formed on one supporting substrate, or the color filter 15 and the lens 17 may be formed on separate supporting substrates. The lens 17 and the color filter 15 can be bonded to the substrate 8 using, for example, a binding member such as an adhesive. The binding member may be disposed on the planarization layer, or the binding member may be disposed on the protection layer 13 when the planarization layer is not disposed.

The lens 17 may be formed on a supporting substrate other than the substrate 8 and may be bonded so as to face the substrate 8 having the light-emission portion 32. In this case, the lens 17 may be fixed to the substrate 8 by a binding member, such as an adhesive, at the end of the light-emitting apparatus such that space is provided between the lens 17 and the protection layer 13 (or the color filter 15). In such a case, the space may be filled with a resin. The resin may have a refractive index smaller than the refractive index n of the lens 17.

Here, application examples in which the light-emitting apparatus of the present embodiments is applied to the exposure light source of a display apparatus, a photoelectric-conversion apparatus, electronic equipment, an illumination apparatus, a moving body, a wearable device, and an electrographic image-forming apparatus will be described using FIGS. 10 to 17.

FIG. 10 is a schematic diagram illustrating an example of the display apparatus using the light-emitting apparatus of the present embodiments. The display apparatus 1000 may include a touch panel 1003, a display panel 1005, a frame 1006, a circuit substrate 1007, and a battery 1008 between an upper cover 1001 and a lower cover 1009. The touch panel 1003 and the display panel 1005 are connected to flexible print circuits FPC 1002 and 1004, respectively. The circuit substrate 1007 is provided with an active element, such as a transistor. The battery 1008 need not be provided if the display apparatus 1000 is not portable equipment and need not be provided at this position even if the apparatus 1000 is portable equipment. The display panel 1005 can be applied to a light-emitting apparatus. The light-emitting apparatus that functions as the display panel 1005 is connected to an active element, such as a transistor, disposed to the circuit substrate 1007 and is operated.

The display apparatus 1000 shown in FIG. 10 may be used in a display portion of a photoelectric-conversion apparatus (image-pickup apparatus) including an optical portion including a plurality of lenses and an image-pickup element that receives light passed through the optical portion and photoelectrically converts it into an electric signal. The photoelectric-conversion apparatus may include a display portion that displays information acquired by the image-pickup element. The display portion may be a display portion exposed to the outside of the photoelectric-conversion apparatus or a display portion arranged in a finder. The photoelectric-conversion apparatus may be a digital camera or a digital camcorder.

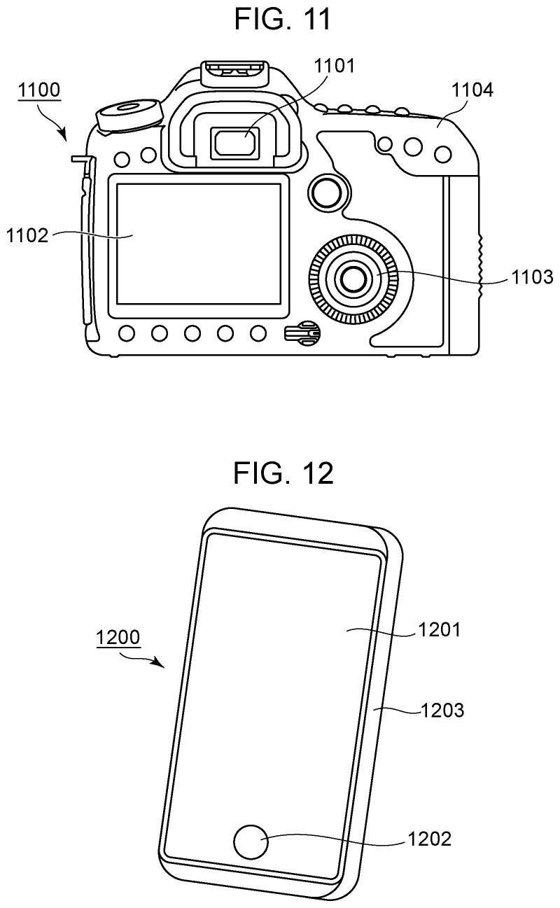

FIG. 11 is a schematic view illustrating an example of the photoelectric-conversion apparatus using the light-emitting apparatus of the present embodiments. The photoelectric-conversion apparatus 1100 may include a view finder 1101, a rear display 1102, an operating portion 1103, and a housing 1104. The photoelectric-conversion apparatus 1100 can also be called an image-pickup apparatus. The light-emitting apparatus of the present embodiments can be applied to display portions, i.e., the view finder 1101 and the rear display 1102. In this case, the light-emitting apparatus may display not only the image to be imaged but also environmental information, an imaging instruction, and so on. The environmental information may be the intensity of external light, the direction of external light, the speed at which a photographic subject moves, the possibility that a photographic subject is shielded by a shielding material, and so on.

Since the optimal timing for imaging is often just a short time, it is better to display the information as soon as possible. Accordingly, a light-emitting apparatus provided with an organic light-emitting device using an organic light-emitting material, such as an organic EL element, may be used in the view finder 1101 or the rear display 1102, because the response speed of the organic light-emitting material is high. The light-emitting apparatus using the organic light-emitting material is suitable for these apparatuses requiring display speed, as compared to a liquid-crystal display apparatus.

The photoelectric-conversion apparatus 1100 includes an optical portion (not shown). The optical portion includes a plurality of lenses and forms an image in a photoelectric-conversion element (not shown) accommodated in the housing 1104 that receives light that has passed through the optical portion. The plurality of lenses can adjust the focal point by adjusting the relative positions thereof. This operation can also be automatically performed.

The light-emitting apparatus may be applied to the display portion of electronic equipment. In such a case, the light-emitting apparatus may have both display and operation functions. Examples of the portable terminal include a portable phone such as a smart phone, a tablet, and a head-mount display.

FIG. 12 is a schematic view illustrating an example of the electronic equipment using the light-emitting apparatus of the present embodiments. The electronic equipment 1200 includes a display portion 1201, an operating portion 1202, and a housing 1203. In the housing 1203, a circuit, a print substrate including the circuit, a battery, and a communication portion may be disposed. The operating portion 1202 may be a button or may be a reaction portion of a touch panel system. The operating portion 1202 may be a biological identification portion that recognizes a fingerprint and unlocks the electronic equipment 1200. The portable equipment including a communication portion can also be referred to as communication equipment. The light-emitting apparatus of the present embodiments can be applied to the display portion 1201.

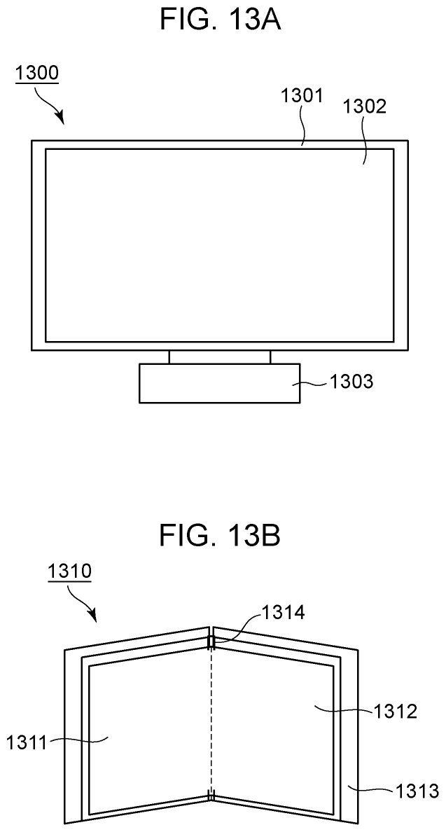

FIGS. 13A and 13B are schematic views illustrating examples of the display apparatus using the light-emitting apparatus of the present embodiments. FIG. 13A is a display apparatus, such as a television monitor and a PC monitor. The display apparatus 1300 includes a frame 1301 and includes a display portion 1302. The light-emitting apparatus of the present embodiments can be applied to the display portion 1302. The display apparatus 1300 may include a base 1303 supporting the frame 1301 and the display portion 1302. The shape of the base 1303 is not limited to that of FIG. 13A. For example, the lower side of the frame 1301 may serve as the base 1303. The frame 1301 and the display portion 1302 may be curved. The radius of curvature may be 5000 mm or more and 6000 mm or less.

FIG. 13B is a schematic view illustrating another example of the display apparatus using the light-emitting apparatus of the present embodiments. The display apparatus 1310 of FIG. 13B is configured to be bendable and is a so-called foldable display apparatus. The display apparatus 1310 includes a first display portion 1311, a second display portion 1312, a housing 1313, and an inflection point 1314. The light-emitting apparatus of the present embodiments can be applied to the first display portion 1311 and the second display portion 1312. The first display portion 1311 and the second display portion 1312 may be a single seamless display apparatus. The first display portion 1311 and the second display portion 1312 can be divided at the inflection point. The first display portion 1311 and the second display portion 1312 may display different images, respectively, or may display a single image by the first display portion and the second display portion.

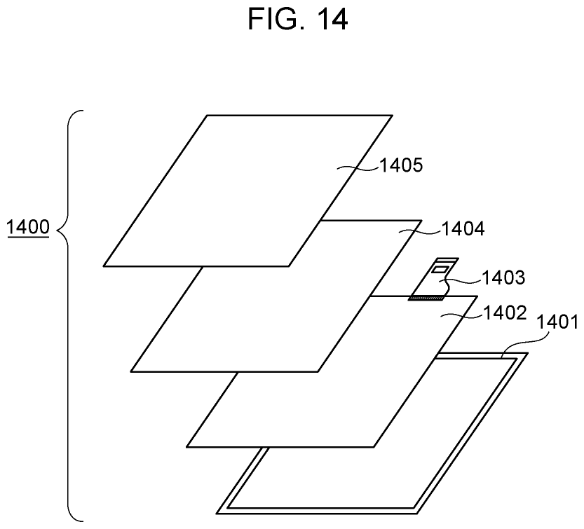

FIG. 14 is a schematic view illustrating an example of an illumination apparatus using the light-emitting apparatus of the present embodiments. The illumination apparatus 1400 may include a housing 1401, a light source 1402, a circuit substrate 1403, an optical film 1404, and light-diffusion portion 1405. The light-emitting apparatus of the present embodiments can be applied to the light source 1402. The optical film 1404 may be a filter for improving the color-rendering property of the light source. The light-diffusion portion 1405 can effectively disperse the light of a light source, such as Light Up, and can deliver light over a wide range. As needed, a cover may be provided at the outermost portion. The illumination apparatus 1400 may include both the optical film 1404 and the light diffusion portion 1405 or may include only one of them.

The illumination apparatus 1400 is, for example, an apparatus for lighting indoors. The illumination apparatus 1400 may emit light of white, neutral white, or any other color from blue to red and may include a light-modulation circuit for modulating them. The illumination apparatus 1400 may include a power-source circuit connected to a light-emitting apparatus that functions as the light source 1402. The power-source circuit is a circuit for converting an alternating voltage into a direct voltage. White has a color temperature of 4200 K, and natural white has a color temperature of 5000 K. The illumination apparatus 1400 may include a color filter. The illumination apparatus 1400 may include a heat-dissipation portion. The heat-dissipation portion releases heat in the apparatus to the outside, and examples thereof include a metal with a high specific heat and liquid silicon.

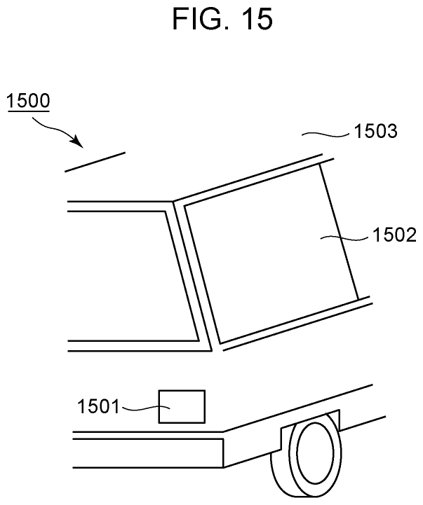

FIG. 15 is a schematic view of an automobile having a tail lamp as an example of a vehicle lighting appliance using the light-emitting apparatus of the present embodiments. The automobile 1500 includes a tail lamp 1501 and may be in a configuration in which the tail lamp 1501 turns on when braking or the like is performed. The light-emitting apparatus of the present embodiments may be used in a head lamp as a vehicle-lighting appliance. The automobile is an example of a moving body, and the moving body may be a ship, a drone, an aircraft, a rail vehicle, an industrial robot, or the like. The moving body may include an airframe and a light appliance provided thereto. The light appliance may indicate the current presence of the airframe.

The light-emitting apparatus of the present embodiments can be applied to the tail lamp 1501. The tail lamp 1501 may include a protection member protecting the light-emitting apparatus that functions as the tail lamp 1501. The protection member may be any material that has a certain degree of strength and is transparent, but may be made of a polycarbonate or the like. The protection member may be a mixture of a carbonate and a furandicarboxylic acid derivative or an acrylonitrile derivative.

The automobile 1500 may include a body 1503 and a window 1502 attached thereto. The window may be a window for checking the front and rear of the automobile or may be a transparent display such as a heads-up display. The light-emitting apparatus of the present embodiments may be used in the transparent display. In this case, the constituent materials, such as an electrode of the light-emitting apparatus, are made of transparent members.

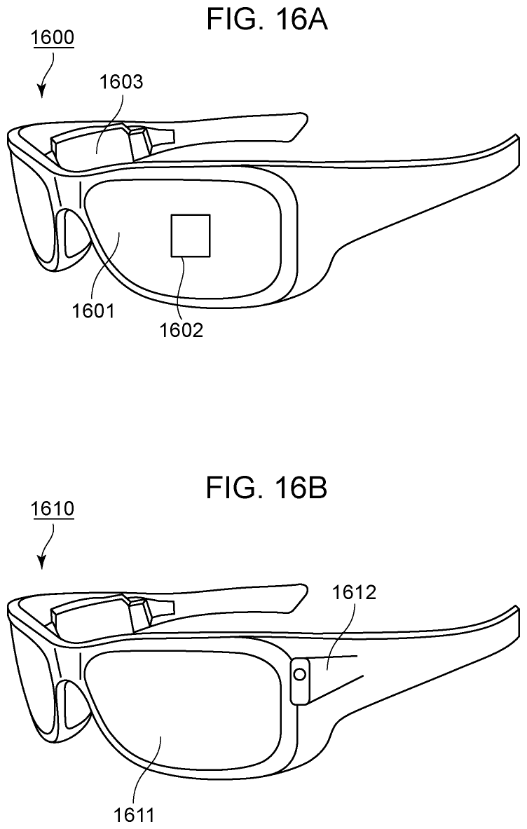

Further application examples of the light-emitting apparatus of the present embodiments will be described with reference to FIGS. 16A and 16B. The light-emitting apparatus can be applied to a system that can be worn as a wearable device, such as smart glasses, a head mount display (HMD), and a smart contact lens. The image display apparatus that is used in such an application example includes an image-pickup apparatus capable of photoelectric conversion of visible light and a light-emitting apparatus capable of emission of visible light.

FIG. 16A describes glasses 1600 (smart glasses) according to one application example. The image-pickup apparatus 1602, such as a CMOS sensor and a SPAD, is provided to the lens 1601 of the glasses 1600 on the front side. The light-emitting apparatus of the present embodiments is provided on the rear side of the lens 1601.

The glasses 1600 further include a controller 1603. The controller 1603 functions as a power source that supplies power to the image-pickup apparatus 1602 and the light-emitting apparatus according to some of the embodiments. The controller 1603 controls the operation of the image-pickup apparatus 1602 and the light-emitting apparatus. An optical system for concentrating light in the image-pickup apparatus 1602 is formed in the lens 1601.

FIG. 16B describes glasses 1610 (smart glasses) according to one application example. The glasses 1610 include a controller 1612, and an image-pickup apparatus corresponding to the image-pickup apparatus 1602 and a light-emitting apparatus are loaded on the controller 1612. In the lens 1611, the image-pickup apparatus in the controller 1612 and an optical system for projecting light emitted from the light-emitting apparatus are formed, and an image is projected to the lens 1611. The controller 1612 functions as a power source for supplying power to the image-pickup apparatus and the light-emitting apparatus and controls the operation of the image-pickup apparatus and the light-emitting apparatus. The controller 1612 may include a gaze-detection portion for detecting the wearer's gaze. The detection of a gaze may use infrared light. The infrared light-emission portion emits infrared light toward an eyeball of a user gazing the displayed image. The imaging portion including a light-receiving element detects reflected light of the emitted infrared light from the eyeball to obtain a pickup image of the eyeball. A decrease in the image quality is reduced by a device for reducing light from the infrared light-emission portion to the display portion in a plan view.

The gaze of a user to the displayed image is detected from the pickup image of the eyeball obtained by imaging with infrared light. The gaze detection using the pickup image of the eyeball can use an arbitrary known method. As an example, a gaze detection method based on the Purkinje image by reflection of irradiation light on the cornea can be used.

More specifically, gaze detection treatment based on a pupil-cornea reflection method is performed. The gaze vector representing the direction (rotation angle) of an eyeball is calculated using the pupil-cornea reflection method based on the image of pupil included in the pickup image of the eyeball and the Purkinje image, and the gaze of the user is detected.

The light-emitting apparatus according to one embodiment of the present disclosure includes an image-pickup apparatus including a light-receiving element and may control the displayed image based on the gaze information of the user from the image-pickup apparatus.

Specifically, the light-emitting apparatus determines the first viewing region closely viewed by the user and the second viewing region other than the first viewing region based on the gaze information. The first viewing region and the second viewing region may be determined by the controller of the light-emitting apparatus, or those determined by an external controller may be received. In the display region of the light-emitting apparatus, the display resolution of the first viewing region may be controlled to be higher than the display resolution of the second viewing region. That is, the resolution of the second viewing region may be lower than the resolution of the first viewing region.

The display region includes a first display region and a second display region different from the first display region, and a high-priority region is determined from the first display region and the second display region based on the gaze information. The first display region and the second display region may be determined by the controller 1612 of the light-emitting apparatus, or those determined by an external controller may be received. The resolution of the high-priority region may be controlled to be higher than the resolution of the region other than the high-priority region. That is, the resolution of a relatively low-priority region may be decreased.

The first viewing region and the high-priority region may be determined using AI. The AI may be a model configured to estimate the angle of the gaze and the distance to a target in front of the gaze from the image of the eyeball using the image of the eyeball and the direction the eyeball in the image is actually looking as teaching data. The AI program may be included in the light-emitting apparatus, an image-pickup apparatus, or an external apparatus. When the external apparatus includes the AI program, the AI program may be transmitted to the light-emitting apparatus through communication.

When display is controlled based on visual detection, the light-emitting apparatus can be applied to smart glasses further including an image-pickup apparatus for imaging the outside. The smart glasses can display the imaged external information in real time.

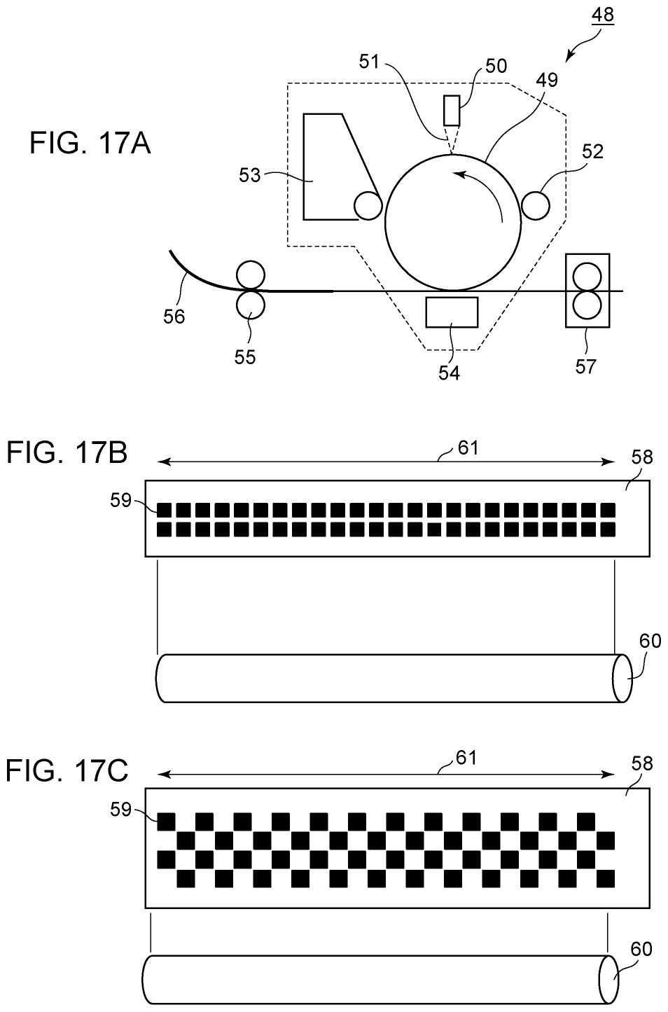

FIGS. 17A to 17C show an image-forming apparatus according to an embodiment of the present disclosure. FIG. 17A is a schematic view of an image-forming apparatus 48 according to an embodiment of the present disclosure. The image-forming apparatus includes a photoreceptor, an exposure light source, a development portion, a charging portion, a transfer device, a transport roller, and a fixing device.

Light 51 is irradiated from the exposure light source 50 to form an electrostatic latent image on the surface of the photoreceptor 49. This exposure light source includes an organic light-emitting device according to the present disclosure. The development portion 53 includes a toner or the like. The charging portion 52 charges the photoreceptor. The transfer device 54 transfers the developed image to a recording medium 56. The transport portion 55 transports the recording medium 56. The recording medium 56 is, for example, paper. The fixing portion 57 fixes the image formed on the recording medium.

FIGS. 17B and 17C are schematic views showing the state in which the exposure light source 58 has a plurality of light-emission portions 59 arranged on a long substrate. 61 is a direction parallel to the axis of the photoreceptor and represents the column direction in which the organic light-emitting devices are arranged. This column direction is the same direction of the axis around which the photoreceptor 60 rotates. This direction can also be called the longitudinal direction of the photoreceptor.

FIG. 17B shows a configuration in which the light-emission portions are arranged along the longitudinal direction of the photoreceptor. FIG. 17C shows a configuration different from that of FIG. 17B and is a configuration in which light-emission portions are arranged alternately in the column direction in each of the first column and the second column. The first column and the second column are arranged in different positions in the row direction.

In the first column, a plurality of light-emission portions are arranged with spaces. The second column includes light-emission portions at the positions corresponding to the spaces between the light-emission portions in the first column. That is, a plurality of light-emission portions are arranged with spaces also in the row direction.

The arrangement of FIG. 17C can be rephrased as, for example, a lattice arrangement, a hound's-tooth check arrangement, or a checkered pattern.

As described above, a display with good image quality and stability for a long time is possible by using an apparatus using the organic light-emitting device according to the present embodiments.

Examples of the light-emitting apparatus will now be described.

### Example 1

Aluminum was formed on a substrate 8 and patterned into a conical shape using photolithography and etching to form reflective layers 9 as a plurality of first electrodes. Subsequently, silicon oxide with a thickness of 65 nm was formed as a material film of an insulation layer 12 so as to cover the plurality of reflective layers 9. In the formed material film, the insulation layer 12 was formed by forming aperture portions for exposing the reflective layers 9 at the respective center portions of the plurality of reflective layers 9. The shape of the aperture portion for exposing a reflective layer 9 was a circle of a radius of 2.0 μm.

As described above, finally, the aperture portions disposed in the insulation layer 12 correspond to the light-emission portions 32. That is, the size and shape of the aperture portion can coincide with the size and shape of the light-emission portion 32 in an orthographic projection to the main surface S1 of the substrate 8. The inclination angle of the reflective layer 9 with respect of the main surface S1 of the substrate 8 at the end of the aperture portion was adjusted to 10 degrees. The shapes of the reflective layers 9 were made the same within the range of manufacturing errors over the whole area in the display region.

After formation of the insulation layer 12, an organic layer 20 was formed on the plurality of reflective layers 9 and the insulation layer 12. Specifically, as a hole-injection layer, compound 1 (the detail is described later, and the same applies to other compounds) was formed in a thickness of 3 nm. Compound 2 was formed in a thickness of 15 nm as a hole-transport layer on the hole-injection layer. Compound 3 was formed in a thickness of 10 nm as an electron block layer on the hole-transport layer. Subsequently, a first light-emission layer was formed in a thickness of 10 nm such that the weight proportion of compound 4 as a host material was 97% and the weight proportion of compound 5 as a light emission dopant was 3%.

Subsequently, a second light-emission layer was formed in a thickness of 10 nm such that the weight proportion of compound 4 as a host material was 98% and the weight proportions of compound 6 and compound 7 as light-emission dopants were each 1%. Subsequently, compound 8 was formed in a thickness of 110 nm as an electron-transport layer on the second light-emission layer. Subsequently, lithium fluoride was formed in a thickness of 1 nm as an electron-injection layer on the electron-transport layer.

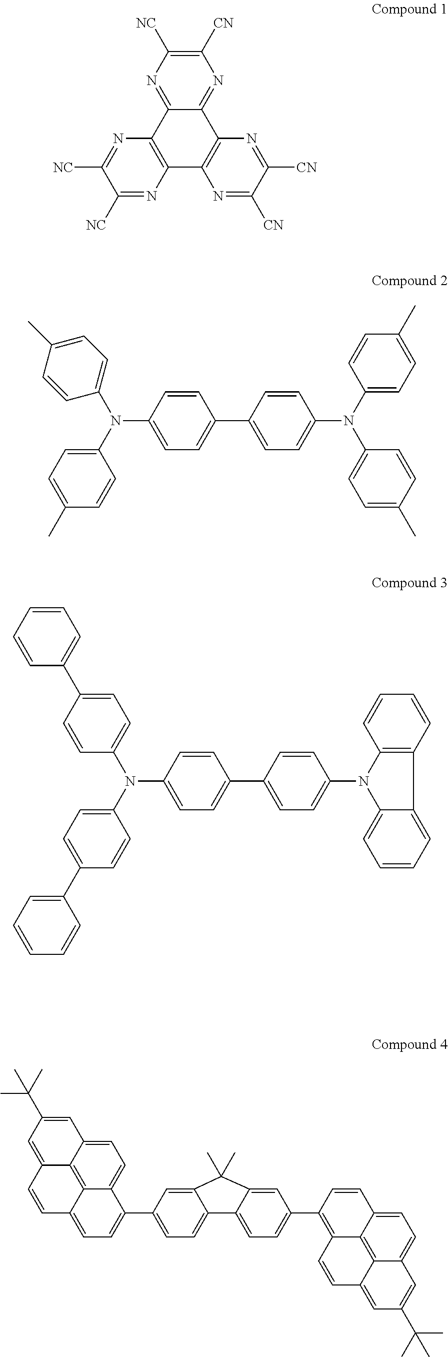

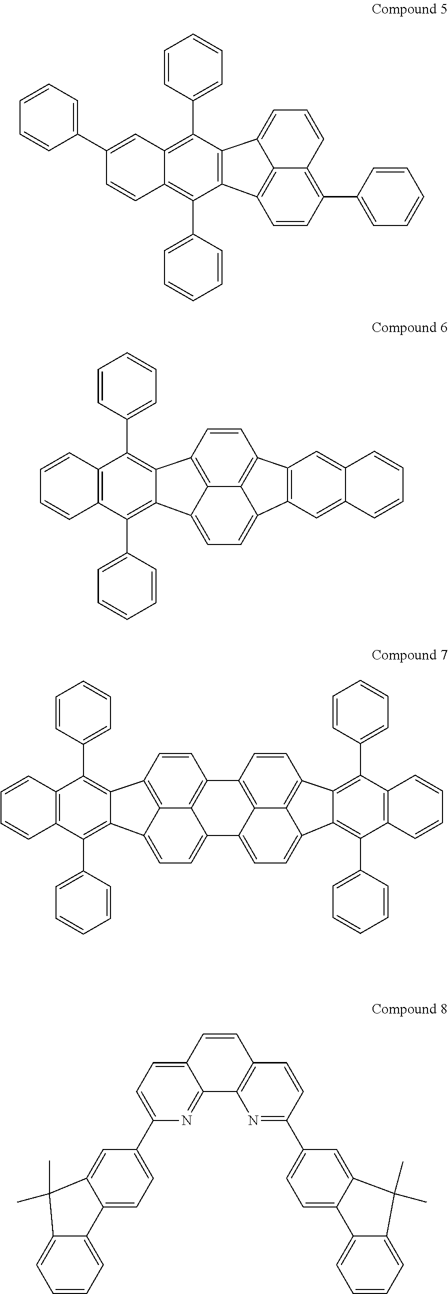

After formation of the organic layer 20, an Mg—Ag alloy was formed in a thickness of 10 nm as a conductive layer 11 as the second electrode on the organic layer 20. The ratio of Mg and Ag was adjusted to 1:1. Then, SiN with a refractive index of 1.97 was formed in a thickness of 2.0 μm as a protection layer 13 on the conductive layer 11 as the second electrode by a CVD method. Subsequently, a planarization layer with a refractive index of 1.55 was formed on the protection layer 13 using a spin-coating method such that the thickness at the position overlapping the first position was 0.2 μm.

Subsequently, color filters 15 with a refractive index of 1.65 were formed in a thickness of 1.6 μm on the planarization layer. The color filter 15r is a color filter that transmits red light, the color filter 15g is a color filter that transmits green light, and the color filter 15b is a color filter that transmits blue light. After formation of the color filter 15, a planarization layer with a refractive index of 1.55 was formed in a thickness of 0.2 μm on the color filter 15 using a spin-coating method.

Subsequently, a lens 17 with a refractive index of 1.52 was formed on the planarization layer using an exposure process and a development process. The curved surface 40 of the lens 17 was a part of a spherical surface. The distance h, which is the difference in the height of the vertex 41 and the end 42 of the curved surface 40 in the normal direction of the main surface of the substrate 8 was adjusted to 2.3 μm, and the distance r between the vertex 41 and the end of the curved surface 40 in the orthographic projection to the main surface of the substrate 8 was adjusted to 3.4 μm. The arrangement was such that the vertex 41 of the lens 17 and the center of the light-emission portion 31 overlap each other in the center of the light-emission region and that the vertex 41 of the lens 17 and the center of the light-emission portion 31 are displaced from each other by 1.5 μm in the outermost periphery of the light-emission region.

In the light-emitting device of the outer peripheral portion of the light-emission region of the above light-emitting apparatus, the inclination angle θ₁ at the first position P1 was 10 degrees, the distance V1 between the first position in the incline portion and the vertex of the lens in a direction parallel to the main surface of the substrate was 2.5 μm, and the distance V1 in the perpendicular direction was approximately 6.3 μm. Accordingly, a straight line satisfying a relationship of tan θ₁≤H₁/V₁ and perpendicular to the line passing through the vertex of the lens and connecting both ends and the normal line of the reflective layer at the first position intersect each other on the light-extraction side of the vertex of the lens.

As a result, the produced light-emitting apparatus increased the amount of light extracted in a direction inclined by 35 degrees from the normal line of the substrate in the light-emitting device in the outer peripheral portion of the light-emission region. Example 2: Example of changing direction of reflection electrode within plane

Subsequently, a light-emitting apparatus of Example 2 will be described. Although in Example 1, the reflective layer 9 as the first electrode was the same shape over the whole area of the light-emission region, in this Example, the reflective layer 9 as the first electrode had different shapes depending on the position in the light-emission region. Specifically, the light-emitting device at the center of the light-emission region did not include an incline portion, but the light-emitting device in the outermost periphery of the light-emission region was in a flat plate shape with an inclination angle of 10 degrees. The configuration other than the above was the same as the example of Example 1.

The produced light-emitting apparatus satisfies the relationship of tanθ₁≤H₁/V₁ as in Example 1, and a straight line that is perpendicular to a line passing through the vertex of the lens and that passes through both ends of the lens and the normal line of the reflective layer at the first position intersect each other on the light-extraction side of the vertex of the lens.

As a result, the produced light-emitting apparatus highly increased the amount of light extracted in a direction inclined by 35 degrees from the normal line of the substrate in the light-emitting device in the outer peripheral portion of the light-emission region. In the pixel at the center of the light-emission region, the amount of light extracted in a front direction could be increased.

Thus, one aspect of the present disclosure can provide technique advantageous for improving the efficiency of light extraction in a diagonal direction.

While the present disclosure has described exemplary embodiments, it is to be understood that some embodiments are not limited to the disclosed exemplary embodiments. The scope of the following claims is to be accorded the broadest interpretation so as to encompass all such modifications and equivalent structures and functions.

This application claims priority to Japanese Patent Application No. 2024-059798, which was filed on Apr. 2, 2024, and Japanese Patent Application No. 2025-011103, which was filed on Jan. 27, 2025, and which are hereby incorporated by reference herein in their entirety.

What is claimed is:

1. A light-emitting apparatus comprising:
a substrate;
a first light-emission portion including a reflective layer disposed on a main surface of the substrate, an organic layer disposed on the reflective layer, and a conductive layer disposed on the organic layer; and
a first lens disposed so as to at least partially overlap the first light-emission portion in a plan view from a direction perpendicular to the main surface of the substrate,
wherein the first lens has a positive power and has a convex shape in an opposite direction to the substrate, and
wherein, in a cross section passing through a vertex of the convex shape of the first lens and perpendicular to the main surface, when a middle point of a line segment connecting one end and another end of the first light-emission portion is defined as a center of the first light-emission portion,
in the plan view, the vertex of the first lens is spaced apart from the center of the first light-emission portion by a first distance, and
in the cross section,
the reflective layer includes an incline portion inclined with respect to the main surface, and
in the incline portion of the reflective layer, when a point of which the distance from the vertex of the first lens in a direction parallel to the main surface is the largest is defined as a first position,
a first straight line passes through both ends of the first lens,
a second straight line extends in a direction perpendicular to the first straight line and passes through the vertex of the first lens,
the second straight line and a normal line of the reflective layer at the first position of the incline portion intersect with each other at one point, and
the one point coincides with the vertex of the first lens or is located on the light-extraction side than the vertex of the first lens.

2. The light-emitting apparatus according to claim 1, wherein, in the cross section, in the incline portion of the reflective layer, an intersection point of a normal line at a position other than the first position and the second straight line coincides with the vertex of the first lens or is located on the light-extraction side of the vertex of the first lens.

3. The light-emitting apparatus according to claim 1, wherein
in the cross section,
when a distance from the vertex of the first lens to the first position in a direction parallel to the main surface is defined as distance H₁ and the distance in a direction perpendicular to the main surface is defined as distance V₁, an inclination angle θ₁ at the first position satisfies a relationship of:
$$tan {θ}_{1} \leq {H}_{1} / {V}_{1} .$$

4. The light-emitting apparatus according to claim 3, wherein
the first lens has a refractive index of n₂, and
at the first position, a relationship of
$${H}_{1} < {V}_{1} / {( {n}_{2}^{2} - 1 )}^{1 / 2}$$
is satisfied.

5. The light-emitting apparatus according to claim 1, wherein
a medium layer is arranged between the conductive layer and the first lens so as to be in contact with the conductive layer,
the medium layer has a refractive index of n₁, and
the inclination angle θ₁ at the first position satisfies a relationship of sinθ₁<1/n₁.

6. The light-emitting apparatus according to claim 5, wherein
the medium layer has a refractive index of n₁,
the first lens has a refractive index of n₂, and
a relationship of n₂≤n₁ is satisfied.

7. The light-emitting apparatus according to claim 5, wherein a color filter is further disposed between the medium layer and the first lens.

8. The light-emitting apparatus according to claim 7, wherein
the first lens has a refractive index of n₂, and the color filter has a refractive index of n₃, and
a relationship of n₂≤n₃ is satisfied.

9. The light-emitting apparatus according to claim 1, wherein, in the cross section,
a point at which a lens inclination angle α formed by the curved surface of the first lens and the main surface is maximum is defined as a second position,
a distance from the vertex of the first lens to the second position in a direction parallel to the main surface of the substrate is defined as r,
a distance from the first position to the second position in a direction perpendicular to the main surface of the substrate is defined as V₂,
a distance from a center of the first light-emission portion to an end of the first light-emission portion in a direction parallel to the main surface of the substrate is defined as H₂, and
when, in a beam emitted in a direction passing through the second position and perpendicular to the main surface of the substrate, a distance of a position, that is spaced apart from the second position by a distance V₂ in a direction perpendicular to the main surface of the substrate from the second position in a direction parallel to the main surface of the substrate, is defined as A, a relationship:
$$A < {H}_{2}$$
is satisfied.

10. The light-emitting apparatus according to claim 1, wherein
in the cross section, when a point at which a lens inclination angle α, formed by the curved surface of the first lens and the main surface of the substrate is maximum, is defined as a second position,
the inclination angle α at the second position is smaller than 90°.

11. The light-emitting apparatus according to claim 1, wherein, the first lens has a refractive index of n₂, and a layer having a refractive index smaller than n₂ is not disposed between the conductive layer and the first lens.

12. The light-emitting apparatus according to claim 1, comprising:
the substrate;
a second light-emission portion including a third reflective layer disposed on the main surface of the substrate, an organic layer disposed on the third reflective layer, and a fourth reflective layer disposed on the organic layer; and
a second lens disposed so as to at least partially overlap the second light-emission portion in the plan view, wherein
the second lens has a positive power,
a vertex of the second lens is spaced apart from a center of the second light-emission portion by a second distance in the plan view, and
the second distance is smaller than the first distance.

13. The light-emitting apparatus according to claim 12, comprising:
a plurality of sets of a light-emission portion and a lens including a set of the first lens and the first light-emission portion and a set of the second lens and the second light-emission portion, wherein
in the plan view, a distance between a center of a region where the plurality of sets are disposed and the center of the first light-emission portion is larger than a distance between the center of the region where the plurality of sets are disposed and the center of the second light-emission portion.

14. The light-emitting apparatus according to claim 12, wherein a distance between the center of the first light-emission portion and an end of the substrate is smaller than a distance between the center of the second light-emission portion and the end of the substrate.

15. The light-emitting apparatus according to claim 14, wherein
the third reflective layer includes an incline portion forming a positive inclination angle in a direction toward the vertex of the second lens together with the main surface of the substrate,
in the incline portion of the third reflective layer, a point of which the distance from the vertex of the second lens in a direction parallel to the main surface is the largest is defined as a third position, and
when a distance from the vertex of the second lens to the third position in a direction parallel to the main surface and a distance from the vertex of the second lens to the third position in a direction perpendicular to the main surface are defined as H₂ and V₂, respectively, the inclination angle θ₂ at the third position satisfies a relationship:
$${V}_{2} \cdot tan {θ}_{2} / {H}_{2} > {V}_{1} \cdot tan {θ}_{1} / {H}_{1} .$$

16. The light-emitting apparatus according to claim 14, wherein the reflective layer and the third reflective layer have approximately the same shape.

17. The light-emitting apparatus according to claim 14, wherein
the third reflective layer includes an incline portion forming a positive inclination angle in a direction toward the vertex of the second lens together with the main surface of the substrate,
in the incline portion of the third reflective layer, a point of which the distance from the vertex of the second lens in a direction parallel to the main surface is the largest is defined as a third position, and
when a distance from the vertex of the second lens to the third position in the parallel direction and a distance from the vertex of the second lens to the third position in a direction perpendicular to the main surface are defined as L3 and H₂, respectively, the inclination angle θ₂ at the third position satisfies a relationship:
$${V}_{2} \cdot tan {θ}_{2} / {H}_{2} \leq {V}_{1} \cdot tan {θ}_{1} / {H}_{1} .$$

18. The light-emitting apparatus according to claim 14, wherein at least a part of the third reflective layer is parallel to the main surface of the substrate.

19. A display apparatus comprising the light-emitting apparatus according to claim 1 and an active element connected to the light-emitting apparatus.

20. A photoelectric-conversion apparatus comprising:
an optical portion including a plurality of lenses;
an image-pickup element that receives light passing though the optical portion; and
a display portion that displays an image, wherein
the display portion displays an image imaged by the image-pickup element and includes the light-emitting apparatus according to claim 1.

21. Electronic equipment comprising:
a housing provided with a display portion; and
a communication portion that is provided to the housing and that communicates with other electronic equipment, wherein
the display portion includes the light-emitting apparatus according to claim 1.

22. An image forming apparatus comprising:
a photoreceptor; and
an exposure light source for exposing the photoreceptor, wherein
the exposure light source includes the light-emitting apparatus according to claim 1.
